(19) United States
(12) Patent Application Publication
(10) Pub. No.: US 2009/0212980 A1
(43) Pub. Date: Aug. 27, 2009

(54) Character input reception apparatus and method for receiving character inputs

(75) Inventor: Hiromi Hisada, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/320,544

(22) Filed: Jan. 29, 2009

(30) Foreign Application Priority Data
Feb. 27, 2008 (JP) 2008-45635

(51) Int. Cl. H03M 11/00

(52) U.S. Cl. 341/28

(57) ABSTRACT

A Japanese Hiragana input character string of “a-i” is displayed while a single Japanese Hiragana character of “ti” is displayed as a display character for representing a “ta” row key assigned with a “ta” row character group of “ta”, “ti”, “tu”, “te”, and “to”. When a user then appoints the “ta” row key, “ti” is added to the tail end of the input character string to newly form the input character string of “a-i-ti” containing three characters. When each of “ka” and “ki” does not effectively follow “a-i-ti” in tree structure index data, a display character for a “ka” row key assigned with “ka”, “ki”, “ku”, “ke”, “ko” is switched into “ku” while skipping “ka” and “ki”. Further, when “tu” does not effectively follow “a-i-ti” in the index data, a display character for the “ta” row key is switched from “ti” into “te” while skipping “tu”.

### CROSS REFERENCE TO RELATED APPLICATION

This application is based on and incorporates herein by reference Japanese Patent Application No. 200845635 filed on Feb. 27, 2008.

### FIELD OF THE INVENTION

The present invention relates to a character input reception apparatus and a relevant method for receiving character inputs.

### BACKGROUND OF THE INVENTION

There is known a character input technology in which when a character input key is displayed in an image display device and a user appoints the displayed character input key, a character presently assigned to the appointed character input key is displayed as an input character.

For example, in an in-vehicle navigation apparatus, multiple input keys are displayed and assigned individually to multiple characters. In Japanese characters, about fifty input keys are assigned to individual Japanese Hiragana characters while in English about twenty input keys are assigned to the individual alphabetical characters.

Such a method has a tendency to require a number of displayed input keys, which cannot be easily accommodated within the size of a single display window. If many character input keys are displayed on the one display window, the size of the display image for the character input key may be required to be small, or the distance between adjoining keys may be required to be small. Such a case may result in deterioration of the user's visibility of the character input keys, and may cause a mistake in operation for appointing a character input key. Such a problem may arise not only in the above navigation apparatus but also in a typical character input reception apparatus.

### SUMMARY OF THE INVENTION

It is an object to provide a technology to improve visibility and operability for users in a character input reception apparatus.

According to a first example of the present invention, a character input reception apparatus is provided as follows. A key display control portion and an input character display control portion are included. The key display control portion is configured to (i) display a plurality of character input keys in a first display portion, each character input key being assigned with a character group including a plurality of characters, and (ii) designate one of the plurality of characters assigned to each character input key so as to display the designated one as a display character for the each character input key. The input character display control portion is configured to, when a user appoints a first character input key among the plurality of character input keys by using an operation section, display, as an input character, a display character for the first character input key in a second display portion. Herein, the key display control portion is further configured to, when the user appoints the first character input key using the operation section, switch a display character for a second character input key, which is one of the plurality of character input keys, from a first character to a second character different from the first character based on a content of a character displayed as an input character in response to appointing the first character input key by the input character display control portion, each of the first character and the second character being included in a character group with which the second character input key is assigned.

As a second example of the present invention, a character input reception apparatus is provided as follows. A key display control portion and an input character display control portion are included. The key display control portion is configured to display in a first display portion a plurality of character input keys, each character input key being assigned with a character group including a plurality of characters. The input character display control portion is configured to, when the user appoints one of the character input keys using an operation section, (i) select, among the plurality of characters assigned to the appointed one of the character input keys, a character corresponding to a number of times in successively appointing the one of the character input keys and (ii) display the selected character as an input character in a second display portion. Herein, the key display control portion is further configured to designate, as a display character for each of the plurality of character input keys, one of the plurality of characters included in the character group assigned to the each of the plurality of character input keys. In addition, the key display control portion is further configured to, in case that the user appoints a first character input key among the plurality of character input keys using the operation section, (i) designate a next input candidate character assigned to a second character input key included in the plurality of character input keys, the next input candidate character being to be designated as a next input character by the input character display control portion if the user subsequently appoints the second character input key once, and (ii) switch a display character for the second character input key into the designated next input candidate character.

Relating to the above examples, as other examples of the present invention, a program storage medium is provided for containing instructions readable and executable by a computer. The instruction is for causing the computer to function as the input character display control portion and the key display control portion included in the character input reception apparatus according to the first or second example.

As another example of the present invention, a method is provided for receiving character inputs using an image display device. The method comprises: (1) displaying a plurality of character input keys in a first display portion of the image display device, the plurality of character input keys at least including a first character input key and a second character input key, each of the plurality of character input keys being assigned with an individual character group including a plurality of individual characters; (2) designating one of the plurality of individual characters assigned to each character input key; (3) displaying a display character for representing the each character input key by using the designated one of the plurality of individual characters; (4) displaying, when the first character input key is appointed, an input character in a second display portion of the image display device by using a display character, which is displayed for representing the first character input key just before the first character input key is appointed; and (5) switching a display character for representing the second character input key from a first character to a second character based on a content of the input character displayed in the second display portion in response to appointing the first character input key, each of the first character and the second character being included in a character group with which the second character input key is assigned.

As yet another example of the present invention, a method is provided for receiving character inputs using an image display device. The method comprises: (1) displaying in a first display portion a plurality of character input keys, the plurality of character input keys at least including a first character input key and a second character input key, each of the plurality of character input keys being assigned with an individual character group including a plurality of individual characters; (2) designating one of a plurality of characters assigned to the second character input key; (3) displaying a display character for representing the second character input key by using the designated one of the plurality of characters assigned to the second character input key; (4) selecting, when the first character input key is appointed, a character corresponding to a number of times in successively appointing the first character input key from among a plurality of characters assigned to the first character input key; (5) displaying the selected character as an input character in a second display portion of the image display device; (6) designating, among a plurality of characters assigned to the second character input key, a next input candidate character, which is estimated to be designated as a next input character following the input character in the second display portion if the second character input key is subsequently appointed once after the first character input key is appointed; and (7) switching a display character for representing the second character input key into the designated next input candidate character in response to appointing the first character input key.

### BRIEF DESCRIPTION OF THE DRAWINGS

The above and other objects, features, and advantages of the present invention will become more apparent from the following detailed description made with reference to the accompanying drawings. In the drawings:

FIG. 1 is a block diagram illustrating a configuration of an in-vehicle navigation apparatus according to an embodiment of the present invention;

FIG. 2 illustrates an example of a data structure of tree structure index data with respect to Japanese Hiragana characters;

FIG. 3 is a flowchart of a program executed by a control circuit;

FIG. 4 is a flowchart of a program executed by the control circuit;

FIG. 5 is a flowchart of a program executed by the control circuit;

FIG. 6 is a flowchart of a program executed by the control circuit;

FIG. 7 is a flowchart of a program executed by the control circuit;

FIG. 8 is a flowchart of a program executed by the control circuit;

FIG. 9 is a default display form of a character input reception display window in a Japanese Hiragana character input mode;

FIG. 10 is a display content in the character input reception display window after the “a” row key is appointed first;

FIG. 11 is a display content in the character input reception display window after a transfer key is appointed next;

FIG. 12 is a display content in the character input reception display window after the “a” row key is appointed next;

FIG. 13 is a display content in the character input reception display window after the “a” row key is appointed again;

FIG. 14 is a display content in the character input reception display window after the “ta” row key is appointed next;

FIG. 15 is a display content in the character input reception display window after the “ka” row key is appointed next;

FIG. 16 is a display content in the character input reception display window after a transfer key is appointed next;

FIG. 17 is an example of a character input reception display window in a numeral character input mode;

FIG. 18 is a default display form of a character input reception display window in an alphabetical character input mode;

FIG. 19 illustrates an example of a data structure of tree structure index data with respect to alphabetical characters; and

FIGS. 20 to 28 are display contents in the character input reception display window when “arkansas” is inputted serially.

### DETAILED DESCRIPTION OF THE PREFERRED EMBODIMENTS

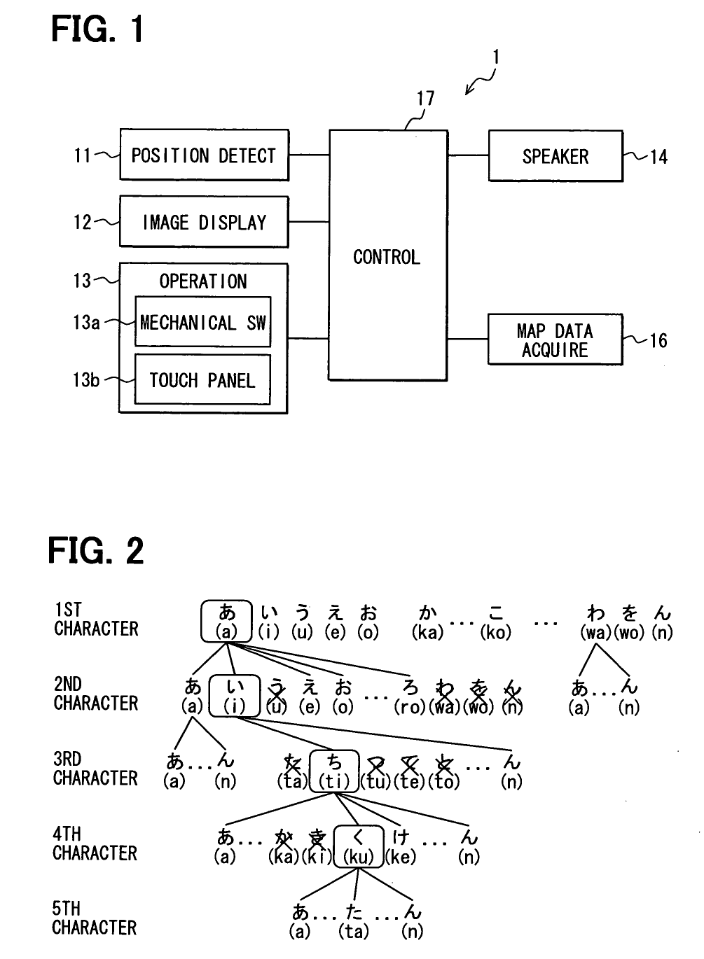

The following describes an embodiment of the present invention. An in-vehicle navigation apparatus 1 is explained below as a character input apparatus according to the embodiment. As shown in FIG. 1, the navigation apparatus 1, which is mounted in a vehicle, includes a position detection device 11, an image display device 12, an operation section 13, a speaker 14, a map data acquisition section 16, and a control circuit 17.

The position detection device 11 includes known sensors or the like such as a geomagnetic sensor, a gyroscope, a speed sensor, and a GPS (Global Positioning System) receiver. The sensors or the like individually output information for designating a present position, a travel direction, and speed of the vehicle to the control circuit 17. The image display device 12 displays images based on video signals outputted from the control circuit 17.

The operation section 13 includes an input device, such as multiple mechanical switches 13a arranged in the navigation apparatus 1 or a touch panel 13b provided in a screen surface of the image display device 12 in superimposition. The operation section 13 outputs signals to the control circuit 17 based on depression of the mechanical switch 13a or touch of the touch panel 13b by a user.

The map data acquisition section 16 is used for data reading and data writing (if possible) with a nonvolatile storage medium such as a DVD, CD, or HDD (Hard Disk Drive). The storage medium stores (i) a program executed by the control circuit 17, (ii) map data for route guidance, or the like.

The map data includes road data and facility data. The road data includes position and kind information on links, position and kind information on nodes, information on connection relation of nodes and links, etc. The facility data contains multiple records for every facility. Each record contains, with respect to a facility as a target, data for indicating name information, location information, land lot number information (also called address information), facility kind information, etc.

Herein, the facility data contains tree structure index data, which functions as an example of dictionary data, for facility names, administrative entities, land lot numbers, etc. FIG. 2 illustrates an example of a data structure of tree structure index data.

For instance, tree structure index data with respect to a recorded target data item signifies a character row order within the whole of the target data item.

In Japanese characters, a recorded target data item is indexed based on pronunciation or reading thereof (i.e., based on the Japanese Hiragana character row order since the Japanese Hiragana character is basically similar to the reading of a word). For instance, a Japanese address mainly containing Japanese Kanji characters of “ [symbol] [symbol] 1 [symbol] reads as a reading series of “ [symbol] (a)- [symbol] (i)- [symbol] (ti)- [symbol] (ke)- [symbol] (n)- [symbol] (to)- [symbol] (yo)- [symbol] (ta)- [symbol] (si)- [symbol] (mo)- [symbol] (to)- [symbol] (ma)- [symbol] (ti)- 1 (i-ti)- [symbol] (ba)- [symbol] (n)- [symbol] (ti)” including sixteen Japanese Hiragana characters and one numeral character of 1 (one). Herein, “ [symbol] [symbol] 1 [symbol] ” as one target data item includes a plurality of words. Further, in the present embodiment, for instance, the Japanese Hiragana character “ [symbol] ” reads as “ke” and is counted as one character; in contrast, the numeral character “1”, which reads “i-ti”, is counted as one character. That is, a numeral character is counted as one character similar to an alphabetical character, which is described later in the explanation with respect to the alphabetical character input mode.

Further, the tree structure index data includes a certain word as a recorded data item; the certain word is represented by a series of n characters. Herein, the tree structure index data teaches which character is allowed to follow i-th (i=0 to n-1) character. In fact, any character is allowed to follow the zero-th character.

Herein, Japanese characters include mainly three types of (i) Kanji character, (ii) Hiragana character, and (iii) Kana character. For instance, a Kanji character “ [symbol] ” is indicated by two serial Hiragana characters “ [symbol] ”, or two serial Kana characters “ [symbol] [symbol] ”. Further, all the three “ [symbol] ”, “ [symbol] ”, and “ [symbol] ” can be converted to Romaji (e.g., Roman character mode) “a-i” and also pronounced like “a-i”. For easy understanding the present embodiment, after each Japanese character, a corresponding Romaji character (signifying the reading of each Japanese character) is added in the explanation in the description and drawings. In a Japanese example of “ [symbol] ( [symbol] [symbol] (a-i-ti))”, the following takes place with reference to FIG. 2. Further, “Aiti” is one of the prefectures (State level administrative entity in Japan); for instance, “Aiti” (also typically represented as “Aichi”) prefecture includes Nagoya city and Toyota city. Herein, with reference to the tree structure index data of FIG. 2, as the first character, any Hiragana character of “ [symbol] (a)” to “ [symbol] (n)” is naturally allowed to follow the zero-th character. After “ [symbol] (a)” is inputted, among the characters of “ [symbol] (a)” to “ [symbol] (n)”, “ [symbol] (a)”, “ [symbol] (i)”, “ [symbol] (e)”, “ [symbol] (o)”, “ [symbol] (ro)” etc. are allowed to follow the first character “ [symbol] (a)” while “ [symbol] (u)”, “ [symbol] (wa)”, “ [symbol] (wo)”, “ [symbol] (n)” etc. are not allowed to follow the first character “ [symbol] (a)”.

In contrast, any character of “ [symbol] (a)” to “ [symbol] (n)” is allowed to follow “ [symbol] (wa)” if “ [symbol] (wa) is inputted as the first character. Further, “ [symbol] (ti)”, “ [symbol] (n)”, etc. are allowed to follow two Japanese Hiragana characters of “ [symbol] (a-i)” while “ [symbol] (ta)”, “ [symbol] (tu)”, “ [symbol] (te)”, “ [symbol] (to)” etc. are not allowed to follow it.

Tracing the tree structure from an initial character by a character-to-character procedure in such tree structure index data enables easy designation of a character, which follows a certain character constituting a corresponding recorded data item. For example, in FIG. 2, when tracing the characters of “ [symbol] (a)”, “ [symbol] (i)”, “ [symbol] (ti)”, “ [symbol] (ku)” along the tree structure, it is easily understood that “ [symbol] (a)”, “ [symbol] (ta)”, “ [symbol] (n)”, etc. are allowed to follow the characters of “ [symbol] (a-i-ti-ku)”.

The control circuit 17 is a microcomputer including a CPU, RAM, ROM, I/O, etc. The CPU reads a program for operating the navigation apparatus 1 from the ROM or the map data acquisition section 16 to execute it. In the execution, the CPU reads information from the RAM, ROM, and the map data acquisition section 16; writes information to the RAM and the storage medium of the map data acquisition section 16, if possible; and communicates data or signals with the position detection device 11, the image display device 12, the operation section 13, and the speaker 14.

The control circuit 17 executes based on programs the following processes: a present position designation process, a map display process, a destination input reception process, a guidance route calculation process, a route guidance process, etc.

The present position designation process is to designate a present position and heading direction of the vehicle based on signals from the position detection device 11 using a technology such as well-known map matching. The map display process is to display a map including a specific area such as a vicinity of the present position of the vehicle in the image display device 12. In such a case, information used for displaying the map is acquired from the map data.

The destination input reception process is to receive an input of a destination by a user via the operation section 13. The details of the destination input reception process are mentioned later.

The guidance route calculation process is to acquire position information on the destination received by the destination input reception process, and calculate an optimal guidance route from the present position to the destination.

The route guidance process is to perform navigation or route guidance when the subject vehicle approaches a guidance point, such as a right/left turn intersection on the guidance route. The process is to output a guidance sound for indicating a right turn, left turn, etc. via the speaker 14, and to display an enlarged view of the guidance point in the image display device 12. The route guidance process thereby navigates the vehicle along the guidance route.

Hereafter, the destination input reception process is explained in detail.

In the destination input reception process, the control circuit 17 determines a destination input method based on a selection operation of the user via the operation section 13. The destination input method can use any one of a facility name, a land lot number, a map, etc. When a map is used, a certain point on the map may be appointed as a destination.

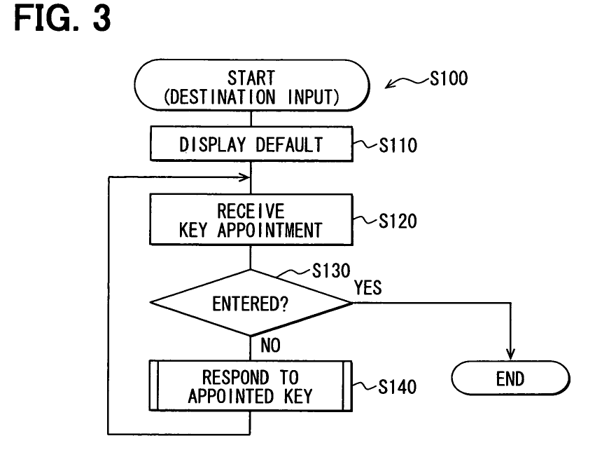

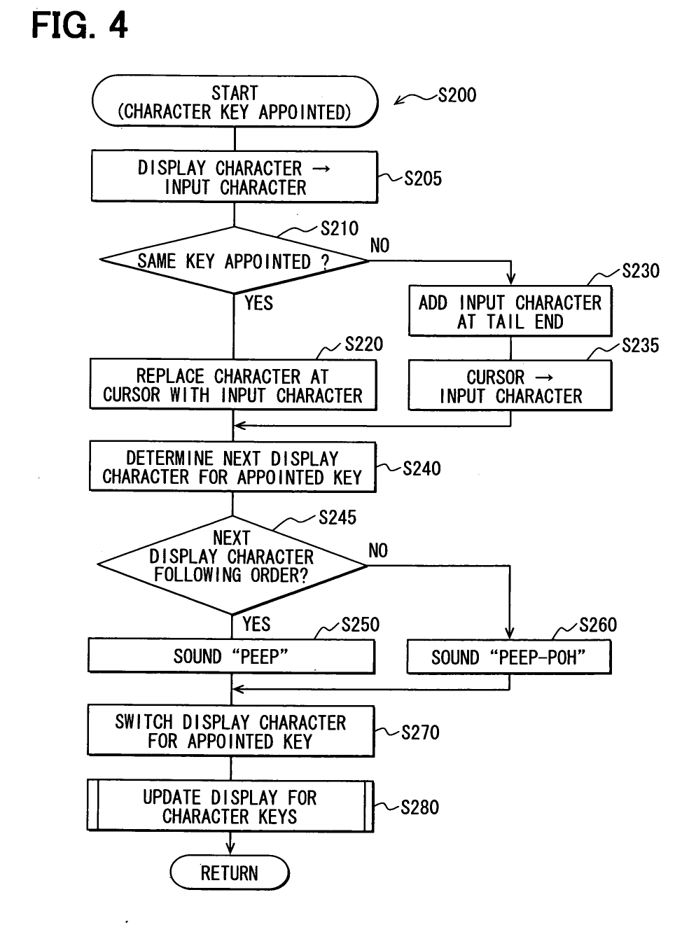

Suppose that it is determined that the input method uses the facility name or the land lot number. The control circuit 17 starts execution of a program 100 illustrated in FIG. 3. Further, FIGS. 4 to 8 illustrate flowcharts of subprograms 200 to 600, which are called in execution of the program 100. All the program and subprograms 100 to 600 are executed by the control circuit 17 as explained above.

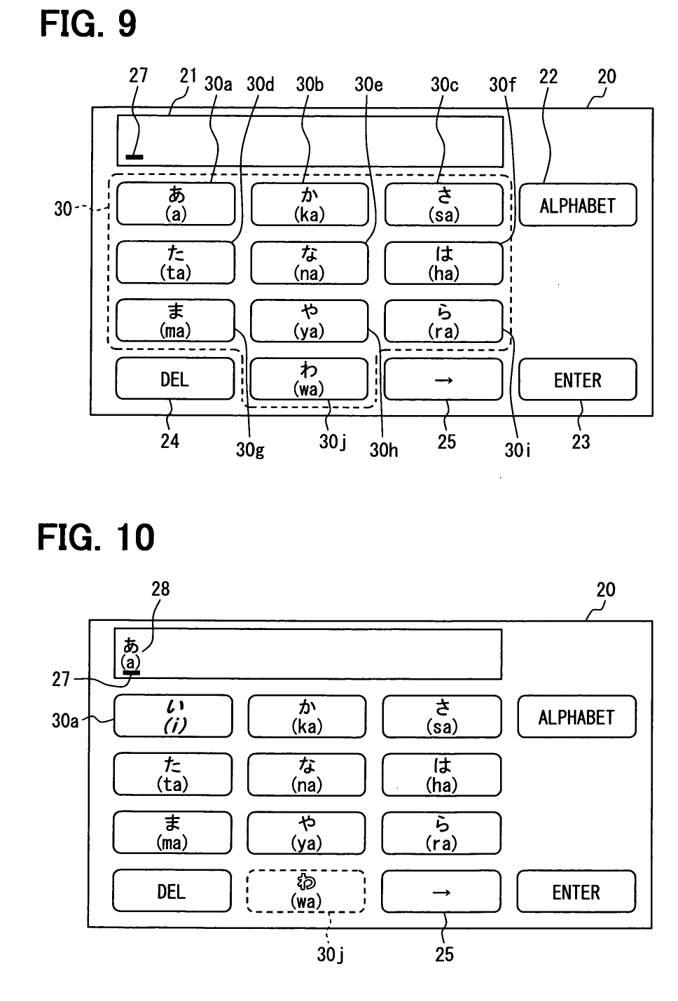

Before starting the explanation of the flowcharts, a configuration of the character input keys are explained with respect to the Japanese Hiragana character input mode with reference to FIG. 9. With respect to FIG. 9, the character input reception window 20 in the image display device 12 contains an input character string field 21, an input mode switch key 22, a determination (or enter) key 23, a delete key 24, a transfer key 25, and multiple Japanese Hiragana character input keys 30 (30a to 30j) as character input keys.

Further, the Japanese Hiragana input keys 30 can be replaced by alphabetical character input keys 40 or numeral character input keys 50, both of which will be explained later. Herein, an area 30, 40, 50 covering the Japanese Hiragana character input keys 30, alphabetical character input keys 40, or numeral character input keys 50 for displaying input keys may be referred to a first display portion in the character input reception window 20 of the image display device 12. Thus, the same reference numbers 30, 40, 50 are used for representing the first display portion and the character keys at the same time. In contrast, the input character string field 21 for displaying an input character may be referred to as a second display portion in the character input reception window 20 of the image display device 12.

The input character string field 21 is an area for displaying an input character string including characters inputted by the user using the operation section 13. A cursor 27, which moves according to the user's operation, is displayed in the left end portion of the input character string field 21 in FIG. 9; namely, the left end portion corresponds to the initial or top character.

Further, the input character string field 21 may be defined to include (i) an input determined portion or character(s), which is not accompanied by the cursor 27 and (ii) an input candidate portion or character, which is accompanied by the cursor 27 (in other words, an input candidate character is defined as being at the position of the cursor 27).

The input mode switch key 22, determination key 23, delete key 24, transfer key 25, and multiple Japanese Hiragana character input keys 30 can be appointed by the user, individually. Appointing such a key can be performed as follows. For instance, a user operates a movement switch of the mechanical switch 13a to thereby allocate a focus target to a corresponding key. Then, the user presses an appointment switch of the mechanical switch 13a to thereby designate the corresponding key as an appointed key. In addition, alternatively, the user touches the position corresponding to a certain key in the touch panel 13b to thereby designate the certain key as an appointed key.

Here, Japanese Hiragana character input keys 30 including ten keys (30a to 30j) are assigned individually with character groups different from each other. Each character group includes all the characters of the same character row. For instance, the “ [symbol] (a)” row key 30a includes “ [symbol] (a)”, “ [symbol] (i)”, “ [symbol] (u)”, “ [symbol] (e)”, and “ [symbol] (o)”. The “ [symbol] (ka)” row key 30b includes “ [symbol] (ka)”, “ [symbol] (ki)”, “ [symbol] (ku)”, “ [symbol] (ke)”, and “ [symbol] (ko)”. The “ [symbol] (sa)” row key 30c includes “ [symbol] (sa)”, “ [symbol] (si)”, “ [symbol] (su)”, “ [symbol] (se)”, and “ [symbol] (so)”. The “ [symbol] (ya)” row key 30h includes “ [symbol] (ya)”, “ [symbol] (yu)”, and “ [symbol] (yo)”. The “ [symbol] (wa)” row key 30j includes “ [symbol] (wa)”, “ [symbol] (wo)”, and “ [symbol] (n)”.

Within each character group, a cyclic character row order is predetermined. For instance, a cyclic character row order can be based on the typical Japanese Hiragana character row order.

In addition, in each character group, an initial character or top character is predetermined in the cyclic character row order. For instance, in each character group, an initial character is assigned to the leading or first character in the typical Japanese Hiragana character writing or reading row direction. For instance, “sa” is defined as the initial character in the character group of the “sa” row key having “sa”, “si”, “su”, “se”, and “so”.

Therefore, if the character group of the “sa” row key 30c is taken for an example, a cyclic character row order with an initial character defined is “sa” →“si”→“su”→“se”→“so”→“sa”→“si”→ . . . The cyclic character row order with an initial character defined is also referred to as an initial-defined cyclic character row order.

In addition, a display character is defined as a display image representing each character input key or a character group thereof in the character input reception window 20. In the default display form in the Japanese Hiragana character input mode shown in FIG. 9, a display character uses each initial character of the character group assigned to each character input key 30a to 30j.

Next, the flowcharts in FIGS. 3 to 8 by the control circuit 17 are explained below with respect to the Japanese Hiragana character input mode, which is one of three input modes to be mentioned later, as a first example of the present embodiment. First, a primary operation is explained with reference to the flowchart in FIG. 3. In starting the program 100 of FIG. 3, at S110, the control circuit 17 displays a character input reception window (or display window) 20 in a default display form in the image display device 12 as shown in FIG. 9. At S120, the processing waits for appointment of the user using the character input reception window 20.

At S130, it is determined whether the determination key 23 is appointed. If appointed, an input character string presently displayed in the input character string field 21 is designated as characters or reading corresponding to the facility name or land lot number of the destination. The destination corresponding to the input character string or reading is designated; then, the destination input reception process is ended. When any key other than the determination key 23 is appointed, the processing corresponding to the appointed key is executed at S140. At S120, another key appointment is thereafter received.

While illustrating a procedure in which the user performs key inputs, the processes by the control circuit 17 according to the procedure are explained using the flowcharts of FIGS. 4 to 8 in addition to FIG. 3.

After the character input reception window 20 appears in the default display form at S110, suppose that the user appoints the “ [symbol] (a)” row key 30a. Then, the control circuit 17 determines that any character key (any one of the Japanese Hiragana character input key 30, the alphabetical character input key 40, and the numerical character input key 50) is appointed at S140, and starts execution of the subprogram 200 illustrated in FIG. 4.

The control circuit 17 designates, as an input character, the display character for the “ [symbol] (a)” row input key 30a having been displayed just before the “ [symbol] (a)” row input key 30a is appointed; namely, “ [symbol] (a)” is designated as an input character at S205 in FIG. 4. At S210, it is determined whether the appointment of the “ [symbol] (a)” row key 30a has successively repeated twice or more. If having repeated, the processing advances to S220. If having not repeated, the processing advances to S230. In the present stage, the appointment of the “ [symbol] (a)” row key 30a has not repeated, S230 is executed.

At S230, the input character designated at S205 is displayed within the input character string field 21. In particular, if a certain input character string is already displayed within the input character string field 21, the input character is added to the tail end of the certain input character string. In addition, when any input character string is not displayed in the input character string field 21 in the present stage, the input character is added to the initial or top position (namely, left end) of the input character string field 21. In the present stage, as illustrated in FIG. 10, the input character “ [symbol] (a)” is displayed at the top or initial position of the input character string field 21. The input character string is thereby formed by one Japanese Hiragana character “ [symbol] (a)”.

Then, at S235, the position of the cursor 27 is allocated at the position at which the input character is added. In other words, the cursor 27 is accompanying the newly added input character while being arranged just beneath the newly added input character as shown in FIG. 10.

Herein, “ [symbol] (a)” of the input character string 28 is accompanied by the cursor 27 so that “ [symbol] (a)” may be identified as being an input candidate character. Further, the cursor 27 can be moved as needed.

Then, at S240, a next display character used for the appointed character input key 30a is designated based on the tree structure index data. Herein, the next display character signifies a next display image or a display character for representing the appointed key (namely, “ [symbol] (a)” row key 30a in the present stage). In addition, the tree structure index data used by each subprograms 200 to 500 is for the facility names or land lot numbers when using facility name input or land lot numbers, respectively, in the present embodiment.

To designate the next display character for the appointed key, the control circuit 17 extracts all character(s) (referred to as effective character(s) or permissible character(s)), which can be a character following a preceding character string based on the tree structure index data, among the characters included in the character group assigned to the appointed character input key 30a. In addition, the preceding character string signifies, among the updated or present input character string, a character string just before the character is inputted newly by the most recently performed key appointment. In other words, the preceding character string can be defined as, of the input character string, the characters excluding a character accompanied by the cursor 27, or as the input determined portion of the input character string.

In the above stage, the preceding character string is a null string, which has no character. Therefore, when the tree structure index data has a data structure illustrated in FIG. 2, effective characters within the character group assigned to the “ [symbol] (a)” row key 30a are all the characters included in the group, i.e., “ [symbol] (a)”, “ [symbol] (i)”, “ [symbol] (u)”, “ [symbol] (e)”, and “ [symbol] (o)”.

Further, among the effective characters, the control circuit 17 designates, as the next display character, a character, which is the leading character (“ [symbol] (i)” in the present stage) after the input character (“ [symbol] (a)” in the present stage) according to the initial-defined cyclic character row order.

At S245, it is determined whether the next display character designated at S240 is directly following the input character according to the initial-defined cyclic character row order. When directly following, the processing advances to S250 while when not directly following, the processing advances to S260. In the present stage, the character “ [symbol] (i)” is the adjoining order to directly follow the input character of “ [symbol] (a)”, S250 is subsequently executed.

At S250, a first sound of “PEEP” is outputted via the speaker 14. Then, at S270, the display character (i.e., “ [symbol] (i)” being highlighted in an enlarged and italic form in FIG. 10 just for easy recognition) for the appointed key 30a is changed to the next display character designated at S240.

At S280, the control circuit 17 executes the character key display update process. In detail, the subprogram 600 illustrated in FIG. 8 is executed. The subprogram 600 executes one cycle of the processing of S610 to S640 with respect to character keys (the Japanese Hiragana character input keys 30 in the present example) contained in the present character input reception window 20. However, only when it is determined at S610 that a character key as a target (also referred to as a “target key”) is not the appointed key, the processing of S620 to S640 is executed. If the target character key is determined to be the appointed key, the target key is immediately changed to a following character key. Therefore, the subprogram 600 executes the processing of S620 to S640 with respect to each of the character keys other than the appointed key.

At S620, it is determined whether the character group assigned to the target key contains an effective character following the input character string with reference to the tree structure index data. When not containing, the processing advances to S630 while when containing, the processing advances to S640.

Under the present stage, according to the tree structure index data, an effective character following “ [symbol] (a)” as the character string exists in the character groups of the row keys 30a to 30i other than the “ [symbol] (wa)” row key 30j. That is, the word which starts from “ [symbol] (a-wa)”, “ [symbol] (a-wo)”, or “ [symbol] (a-n)” does not exist in the tree structure index data.

Thereby in the processing for the [symbol] (wa)” row key 30j, the control circuit 17 executes S630, where the display character of the target key (namely, “ [symbol] (wa)” row key 30j) is switched into the initial character of the character group of the target key. Furthermore, as illustrated in FIG. 10, the display of the target key 30j is toned down (i.e., shown in an outlined form). Furthermore, it is designed that the user is prevented from appointing the target key. That is, the operation is disregarded even if the user operates to appoint the target key.

Further, with respect to other keys except the “ [symbol] (wa)” row key 30j and “ [symbol] (a)” row key 30a (i.e., the appointed key), the control circuit 17 executes S640.

At S640, when the target key is set to be toned down in the display and nonenterable, such setting of the target key is released first.

Furthermore, at S640, an effective character following the input character string is extracted from the character group assigned to the target key with reference to the tree structure index data. Among the extracted characters, the leading character based on the initial-defined cyclic character row order. The designated character is thereby regarded as a display character for the target key. The processing about the target key is ended after S630 and S640. In this stage, the display content of the character input reception window 20 is in the state illustrated in FIG. 10.

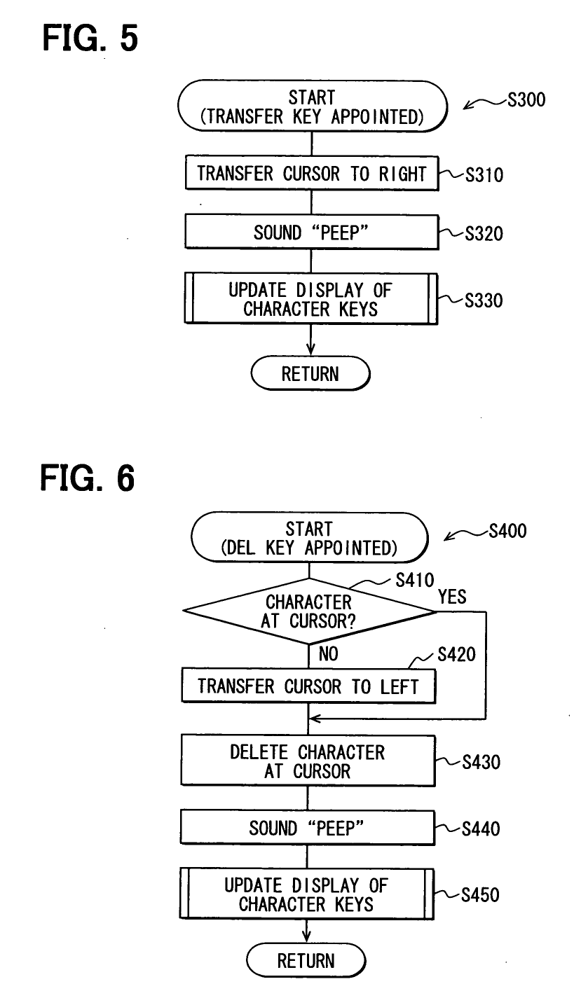

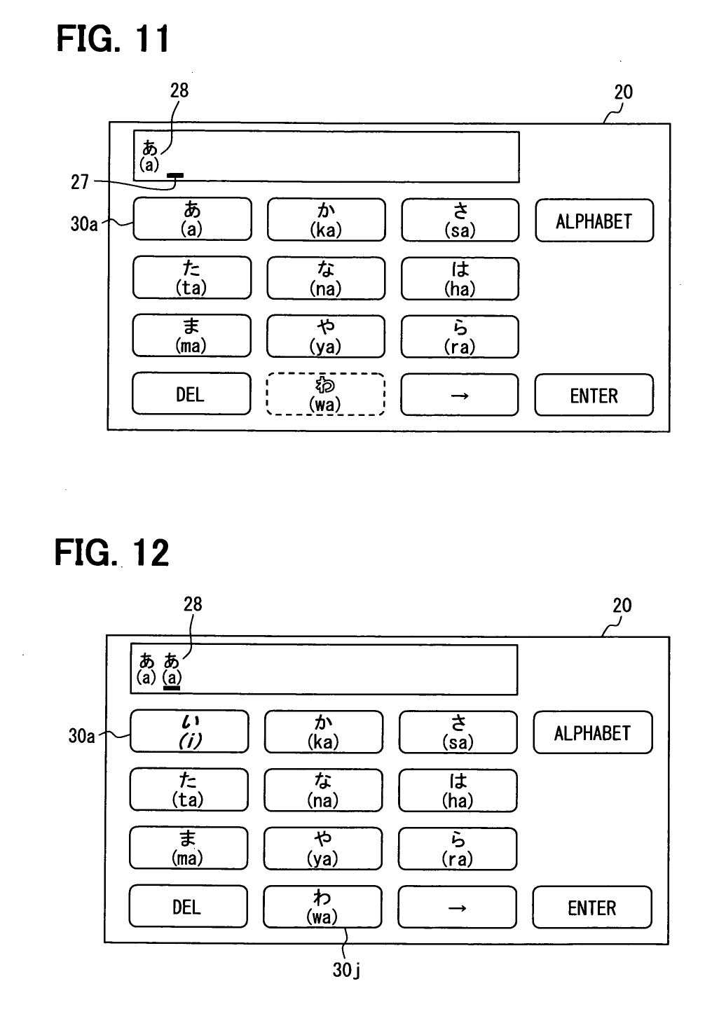

In this stage, suppose that the user subsequently appoints the transfer key 25. The explanation following the appointment of the transfer key 25 is made basically with reference to FIG. 11. In such a case, at S140, the control circuit 17 executes the subprogram 300 in FIG. 5. Herein, at S310, the cursor 27 is shifted to the right by one character space. Then, the first sound of “PEEP” is outputted via the speaker 14 at S320. Then, the control circuit 17 executes the subprogram 600 in FIG. 8 for updating the display of the character input keys (Japanese Hiragana characters 30 in the present example.)

In the present execution of the subprogram 600, the appointed key is the transfer key 25; thus, the processing of S620 to S640 is executed for each of all the character input keys 30a to 30j including the “ [symbol] (a)” row key 30a. The processing with respect to the Japanese Hiragana character input keys 30 other than the “ [symbol] (a)” row key 30a is the same as that of the previous execution of the subprogram 600; thus, there is no change in the individual display characters.

However, the display may change about the “ [symbol] (a)” row key 30a. Suppose that there is “ [symbol] (a)” as an effective character following the “ [symbol] (a)” in the tree structure index data in the present example. In such a case, with respect to the “ [symbol] (a)” row key 30a, the determination at S620 is affirmed, so S640 is then executed. Herein, as shown in FIG. 11, the display character of the target key of the “ [symbol] (a)” row key 30a is switched into “ [symbol] (a)”.

Next, suppose that the user subsequently appoints the “ [symbol] (a)” row key 30a. Then, the control circuit 17 executes the subprogram 200 of FIG. 4 at S140. At S205, the “ [symbol] (a)” is set to the input character. At S210, it is determined that the appointment of the “ [symbol] (a)” row key 30a has not successively repeated. Then, at S230, as illustrated in FIG. 12, the input candidate character “ [symbol] (a)” is added at the tail end of the input character string 28 of “ [symbol] (a)”. Then, the cursor 27 is moved to the added input character at S235. The input character string 28 is thereby formed by two Japanese Hiragana characters “ [symbol] (a)- [symbol] (a)”, as shown in FIG. 12.

At S240, according to the tree structure index data of FIG. 2, among the effective characters following the first “ [symbol] (a)” as the preceding input character string or input determined character string, the leading character next to the second “ [symbol] (a)” as the input character according to the initial-defined cyclic character row order is the character “ [symbol] (i)”; thus, the next display character is switched to the character “ [symbol] (i)”.

Then, at S245, it is determined that the next display character “ [symbol] (i)” follows the input character “ [symbol] (a)” according to the initial-defined cyclic character row order. Then, the first sound of “PEEP” is outputted via the speaker 14 at S250.

Then, at S270, the display character for the appointed key 30a is changed to the next display character “ [symbol] (i)”. In FIG. 12, “ [symbol] (i)” at the character input key 30a is highlighted in the enlarged and italic form just for easy recognition. Then, in order to update other character keys at S280, the subprogram 600 of FIG. 6 is executed. In the present execution of the subprogram 600, for example, all the Japanese Hiragana characters may be effective characters, which can follow the input character string “ [symbol] (a)- [symbol] (a)”. In such a case, at S640, as illustrated in FIG. 12, the display characters for the Japanese Hiragana character input keys 30b to 30j other than the “ [symbol] (a)” row key 30a are all the initial characters in the initial-defined cyclic character row order, and are allowed to be appointed by the user. Therefore, the “ [symbol] (wa)” row key 30j returns from the nonenterable state to the enterable state and toning down is released.

Next, suppose that the user subsequently appoints the “ [symbol] (a)” row key 30a again. Then, the control circuit 17 executes the subprogram 200 of FIG. 4 at S140. At S205, the display character “ [symbol] (i)” is designated as an input character. At S210, it is determined that the appointment of the “ [symbol] (a)” row key 30a has successively repeated. Then, the processing advances to S220.

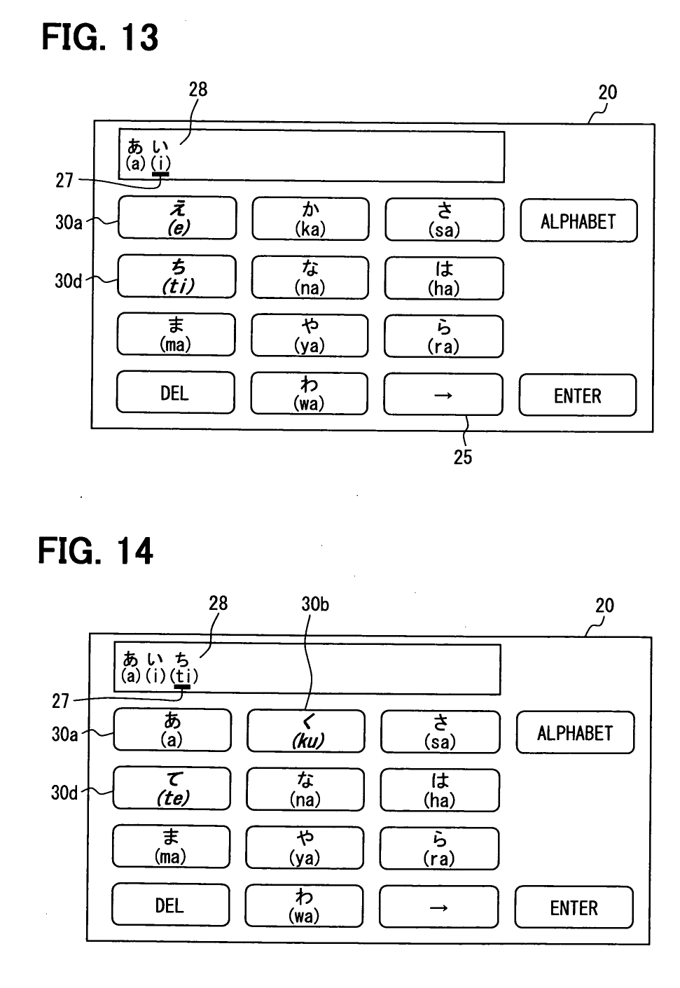

At S220, the character accompanied by the cursor 27 (namely, the character at the tail end of the input character string) is replaced by the input character. Then, in the present stage, as illustrated in FIG. 13, the input character string 28 changes to “ [symbol] (a)- [symbol] (i)”.

Then, according to the tree structure index data of FIG. 2, among the effective characters following “ [symbol] (a)” as the input determined character string, the character “ [symbol] (e)” is the leading character next to the input character “ [symbol] (i)” according to the initial-defined cyclic character row order. The next display character is thus changed into the character “ [symbol] (e)”.

Then, at S245, it is determined, according to the initial-defined cyclic character row order, that the next display character “ [symbol] (e)” is not directly following (or adjoining) the input character “ [symbol] (i)”. Then, at S260, a second sound of “PEEP-POH”, which is longer than the first sound “PEEP”, is outputted via the speaker 14.

Suppose a user, who is experienced in how the initial-defined cyclic character row order takes place, appoints the “ [symbol] (a)” row key 30a. In such a case, the user can recognize via sounds whether (i) the character at the tail end of the input character string appears according to the cyclic character row order or (ii) the character at the tail end of the input character string appears while partially skipping the cyclic character row order. When “PEEP” sound is outputted, it is unnecessary to confirm the display character of the character input key by the eye. Only when “PEEP-POH” sound is outputted, it is necessary to confirm the display character of the appointed key (namely, “ [symbol] (a)” row key 30a) by the eye.

Then, at S270, the display character for the appointed key 30a is changed to the next display character “ [symbol] (e)” as shown in FIG. 13. The user can thus also designate any one of the characters other than the display character of the appointed key 30a as an input character by appointing or selecting successively the appointed key 30a.

Then, in order to update other character keys at S280, the subprogram 600 of FIG. 6 is executed. In the present execution of the subprogram 600, for example, only “ [symbol] (ta)”, “ [symbol] (tu)”, [symbol] (te)”, “ [symbol] (to)” are not effective characters following “ [symbol] (a-i)” with respect to character rows other than the “ [symbol] (a)” row. With respect to the Japanese Hiragana character input keys 30 other than the “ [symbol] (a)” row key 30a and “ [symbol] (ta)” row key 30d, the display characters individually turn into the corresponding initial characters in the initial-defined cyclic character row order while being able to be appointed by the user, at S640 succeeding S620, illustrated in FIG. 13.

In contrast, with respect to the “ [symbol] (ta)” row key 30d, the processing undergoes S640 after S620 as follows. The “ [symbol] (ta)” row key 30d is enabled to be appointed by the user. With reference to the tree structure index data, only the effective character “ [symbol] (ti)” following the input character string “ [symbol] (a-i)” can be extracted from the character group of the target key 30d. This is because, as explained above, “ [symbol] (ta)”, “ [symbol] (tu)”, [symbol] (te)”, “ [symbol] (to)” are not effective characters following “ [symbol] (a-i)”. Thus, “ [symbol] (ti)” is naturally designated. The designated character “ [symbol] (ti)” is thereby designated as the display character for the target key 30d, as shown in the enlarged and italic form in FIG. 13.

Next, suppose that the user subsequently appoints the “ [symbol] (ta)” row key 30d. The relevant explanation below is referred to the display content in FIG. 14. The control circuit 17 executes the subprogram 200 of FIG. 4 at S140. At S205, the display character “ [symbol] (ti)” is designated as an input character. At S210, it is determined that the appointment of the “ [symbol] (ta)” row key 30a has not successively repeated. Then, at S230, as illustrated in FIG. 14, the input character “ [symbol] (ti)” is added as an input character at the tail end of the input character string 28 “ [symbol] (a-i)”. Then, the cursor 27 is moved to the position of the added input character at S235. The input character string 28 is thereby formed by three Japanese Hiragana characters “ [symbol] (a-i-ti)”, as shown in FIG. 14.

Then, at S240, the next display character for the appointed key (“ [symbol] (ta)” row key 30d in the present stage) is determined. Herein, there is existing only one effective character following the input character string among the character group of the appointed key 30d at the stage just prior to the appointment of the input key 30d. In such a case, note that an exceptional processing takes place for determining a next display charater for an appointed key at S240. That is, an effective character is extracted with respect to the input character string “ [symbol] (a-i-ti)” appearing at S240 instead of the preceding character string (i.e., input determined character string) “ [symbol] (a-i)” at S240. Among thus extracted effective character(s), the character leading next to the input character “ [symbol] (ti)” in the initial-defined cyclic character row order is turned into the next display character of the appointed key 30d.

For instance, among the effective characters extracted with respect to the input character string “ [symbol] (a-i-ti)” appearing at S240 instead of the preceding character string “ [symbol] (a-i)” at S240, when the character leading next to the input character “ [symbol] (ti)” in the initial-defined cyclic character row order is determined to be the Japanese Hiragana character “ [symbol] (te)”, the next display character of the appointed key 30d is turned into “ [symbol] (te)”.

The reason for using such an exceptional processing is following. The above case is that there is existing only one effective character following the input character string among the character group of the appointed key 30d at the stage just prior to the appointment of the input key 30d. Since the user appointed the appointed key 30d under such a case, it is assumed that the user wanted to input the display character for the appointed key 30d instead of other characters of the character group of the appointed key 30d.

In addition, in case that such processing is executed at S240, if the user subsequently appoints the “ [symbol] (ta)” row key 30d again, the determination result at subsequent S210 becomes exceptionally negative. Thus, when the user further appoints the same appointed key 30d, it can be saved in time and work to appoint the transfer key 25.

Then, at S245, it is determined that the next display character “ [symbol] (te)” does not follow the input character “ [symbol] (ti)” according to the initial-defined cyclic character row order. Then, the second sound of “PEEP-POH” is outputted via the speaker 14 at S260.

In addition, regardless of whether the next display character “ [symbol] (te)” is a character following the input character “ [symbol] (ti)” according to the initial-defined cyclic order at S245, a third sound, which is different from the first sound “PEEP” and the second sound “PEEP-POH” may be alternatively outputted via the speaker 14. Thus, the user can be notified, by sounds, of the exceptional state in which even if the same “ [symbol] (ta)” row key 30d is successively appointed, the input character is not substituted but added to the tail end of the input character string.

Then, at S270, the display character for the appointed key 30d is changed to the next display character “ [symbol] (te)”. Then, in order to update other character keys at S280, the subprogram 600 of FIG. 6 is executed.

In the present execution of the subprogram 600, for example, only “ [symbol] (ka)” and “ [symbol] (ki)” are not effective characters following “ [symbol] (a-i-ti)” as the input character string with respect to character rows other than the “ [symbol] (ta)” row. With respect to the Japanese Hiragana character input keys 30 other than the “ [symbol] (ta)” row key 30d and “ [symbol] (ka)” row key 30b, the display characters individually turns into the corresponding initial characters in the initial-defined cyclic character row order while being able to be appointed by the user, at S640 subsequent to S620, as shown in FIG. 14. Therefore, the display character for the “ [symbol] (a)” row key 30a changes from “ [symbol] (e)” to “ [symbol] (a)”.

In contrast, with respect to “ [symbol] (ka)” row key 30b, the following takes place at S640 subsequent to S620. The input key 30b is enabled to be appointed by the user. The effective characters “ [symbol] (ku)”, “ [symbol] (ke)”, and “ [symbol] (ko)” following “ [symbol] (a-i-ti)” are extracted among the character group of the target key 30b with reference to the tree structure index data. Among the extracted characters, the leading character “ [symbol] (ku)” is designated based on the initial-defined cyclic row order. The designated character “ [symbol] (ku)” is assigned to the display character for the target key 30b as illustrated in FIG. 14.

Next, suppose that the user subsequently appoints the “ [symbol] (ka)” row key 30b. The relevant explanation below is referred to the display content in FIG. 15. The control circuit 17 executes the subprogram 200 of FIG. 4 at S140. At S205, the display character “ [symbol] (ku)” is designated as an input character. At S210, it is determined that the appointment of the “ [symbol] (ka)” row key 30b has not successively repeated. At S230, the input character “ [symbol] (ku)” is added at the tail end of the input character string 28 of “ [symbol] (a-i-ti)”. Then, the cursor 27 is moved to the position of the added input character of “ [symbol] (ku)” at S235. The input character string 28 is thereby formed by four Japanese Hiragana characters “ [symbol] (a)- [symbol] (i)- [symbol] (ti)- [symbol] (ku)”, as shown in FIG. 15.

Herein, suppose the following case with reference to the tree structure index data of FIG. 2. Among the effective characters following “ [symbol] (a-i-ti)” as the preceding character string or input determined character string, the character “ [symbol] (ke)” is in the highest order (i.e., leading order) next to the input character “ [symbol] (ku)”, according to the initial-defined cyclic character row order relative to the character group of the “ [symbol] (ka)” row key 30b. In such a case, at S240, the next display character of the appointed key 30b is designated as “ [symbol] (ke)”. Then, at S245, it is determined that the next display character “ [symbol] (ke)” adjoining the input character “ [symbol] (ku)” according to the initial-defined cyclic character row order. Then, the first sound of “PEEP” is outputted via the speaker 14 at S250.

Then, at S270, the display character for the appointed key 30b is changed to the next display character “ [symbol] (ke)”. Then, in order to update other character keys at S280, the subprogram 600 of FIG. 8 is executed. In the present execution of the subprogram 600, for example, all the Japanese hiragana characters other than those of the “ [symbol] (ka)” row key 30b are assumed to be effectively following the input character string “ [symbol] (a-i-ti-ku)”. In such a case, with respect to all the input keys 30 other than the “ [symbol] (ka)” row key 30b, the following takes place at S640 subsequent to S620. The display characters individually turns into the corresponding initial characters in the initial-defined cyclic order while being able to be appointed by the user. Therefore, the display character for the “ [symbol] (ta)” row key 30d changes from the character “ [symbol] (te)” to the character “ [symbol] (ta)”.

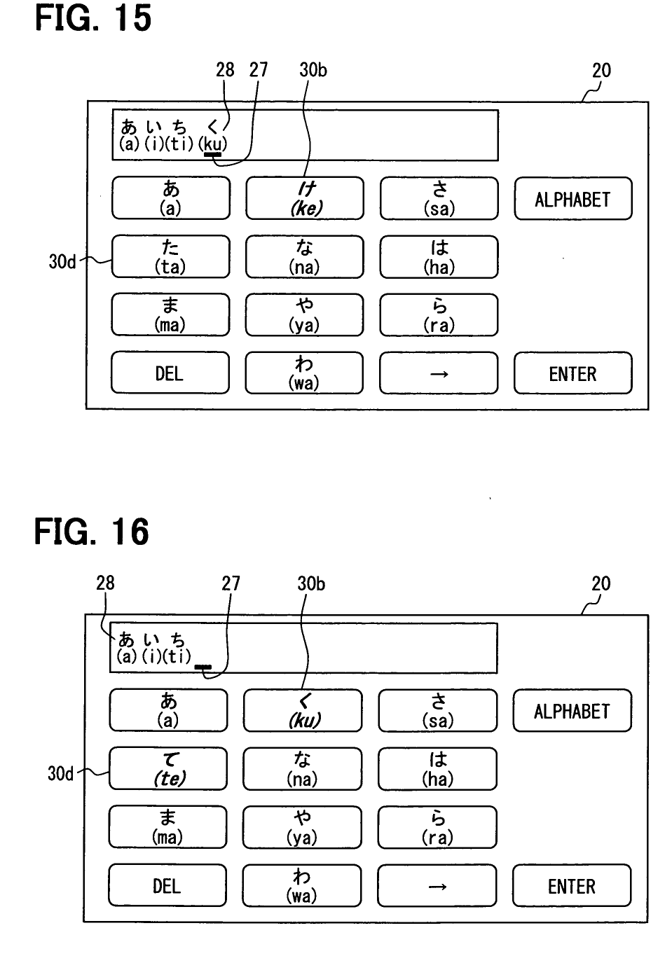

Next, suppose that the user subsequently appoints the delete key 24. The relevant explanation below is referred to the display content in FIG. 16. The control circuit 17 executes the subprogram 400 of FIG. 6 at S140. When it is determined at S400 that a character accompanied by the cursor 27 (i.e., a character at the cursor 27) is not displayed, i.e., that a character is not displayed at the present position of the cursor 27, the cursor 27 is shifted to the left by the single character space at S420. The character, which is at the position of the cursor 27, is erased at S430, as illustrated in FIG. 16. The first sound “PEEP” is outputted via the speaker 14 at S440.

Furthermore, the control circuit 17 executes the subprogram 600 of FIG. 8 for the update of the display for the character keys at S450. In the present execution of the subprogram 600, the appointed key is the transfer key 25; thus the processing of S620 to S640 is executed for all the character input keys 30a to 30j. In the present stage, the input character string returns to “ [symbol] (a-i-ti)”, so the display characters of the Japanese Hiragana character input keys 30 become the same as those in FIG. 14.

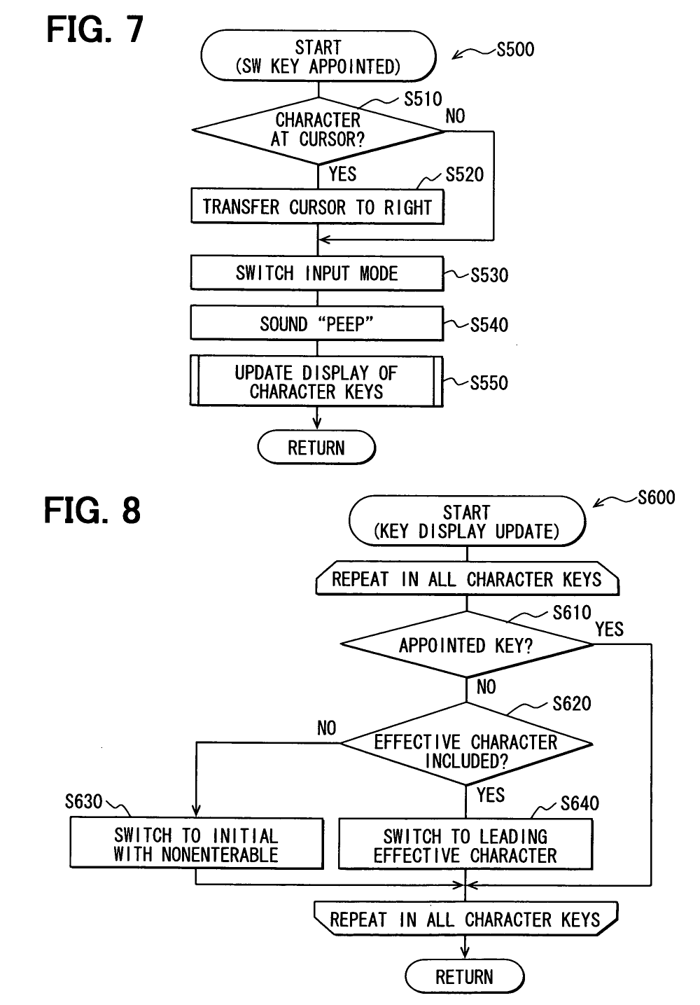

Here, the case where the user appoints the input mode switch key 22 is explained. When the key appointed at S120 is the input mode switch key 22, the control circuit 17 starts execution of the subprogram 500 illustrated in FIG. 7. When it is determined at S510 that a character is displayed at the present position of the cursor 27 (i.e., when a character with the cursor 27 is present), the cursor 27 is shifted to the right by the single character space at S520.

Then, the control circuit 17 toggles or switches to the next input mode at S530. In the present embodiment, the input mode includes three types of (i) Japanese Hiragana character input mode, (ii) Alphabetical character input mode, and (iii) numeral character input mode. The toggling to the next input mode signifies changing the input modes according to the cyclic input mode order recited in the foregoing order. In addition, in the default character input reception window 20 at S110, the input mode is Japanese Hiragana character input mode while the input mode switch key 22 has a display of “ALPHABET”. Thus, at the present stage, the input mode is switched into the Alphabetical character input mode at S530.

The control circuit 17 outputs the first sound “PEEP” via the speaker 14 at S540. Then, by executing the subprogram 600 of FIG. 8, the character input reception window 20 relative to the input mode after the toggling at S530 is displayed in the image display device 12 at S550. The processing at S140 is then ended.

(Numeral Character Input Mode)

Next, the explanation is supplemented with respect to the numeral character input mode as a second example of the present embodiment.

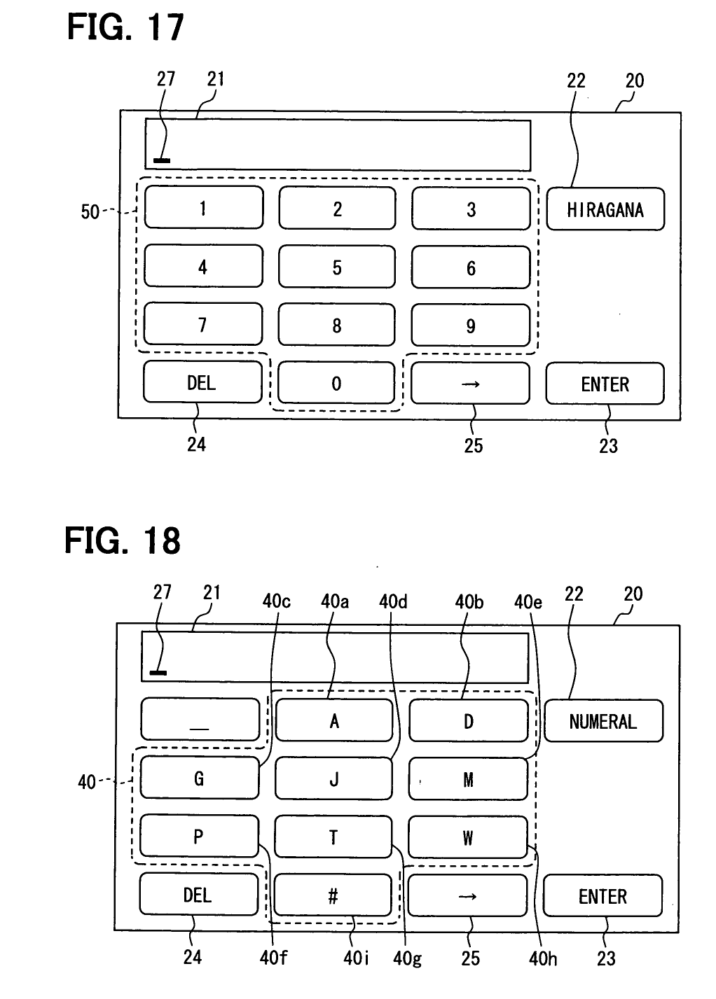

FIG. 17 is an example of a character input reception display window 20 in the numeral character input mode. Herein, in FIG. 17, the same components as those in the character input reception window 20 in FIG. 9 are assigned with the identical reference numerals. Note that the input mode switch key 22 is represented by “HIRAGANA”, which signifies that the Hiragana character input mode will take place when the input mode switch key 22 is appointed next.

The character input reception window 20 in the numeral character input mode replaces the Japanese Hiragana character input keys 30 in the Hiragana character input mode with multiple numerical character input keys 50, which can be individually appointed by the user. Here, each of the numeral character input keys 50 including ten keys is assigned with a single individual numeral (0 to 9) as shown in FIG. 17. In the numeral character input mode, the display character for each of the individual numeral character input keys 50 does not change.

In the numeral character input mode, the subprogram 600 of FIG. 8 is executed by the display update process at S550 in FIG. 7. In addition, in the numeral character input mode, also when the numerical character input key 50 is appointed, the control circuit 17 executes the subprogram 200. Note that in such a case, the processing advances from S205 to S230 while skipping S210; the processing advances from S235 to S250 while skipping S245; and the processing advances from S260 via S270 to S280.

(Alphabetical Character Input Mode)

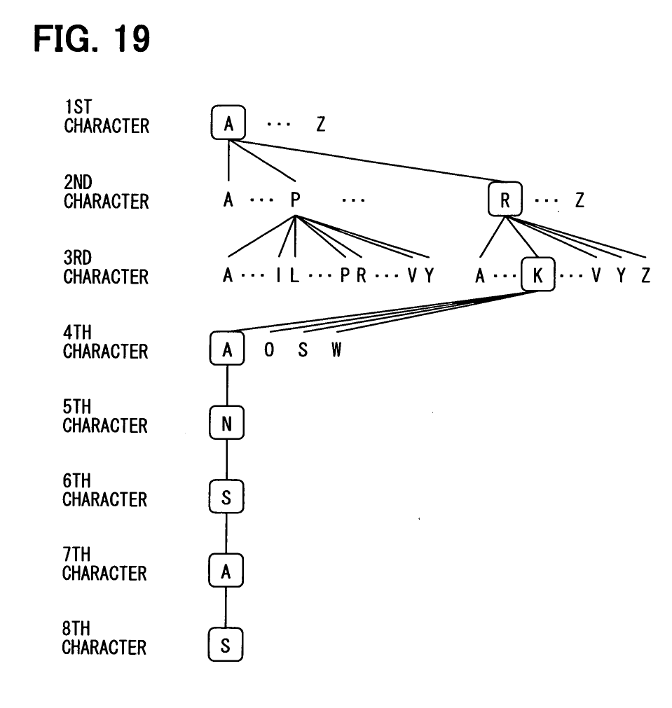

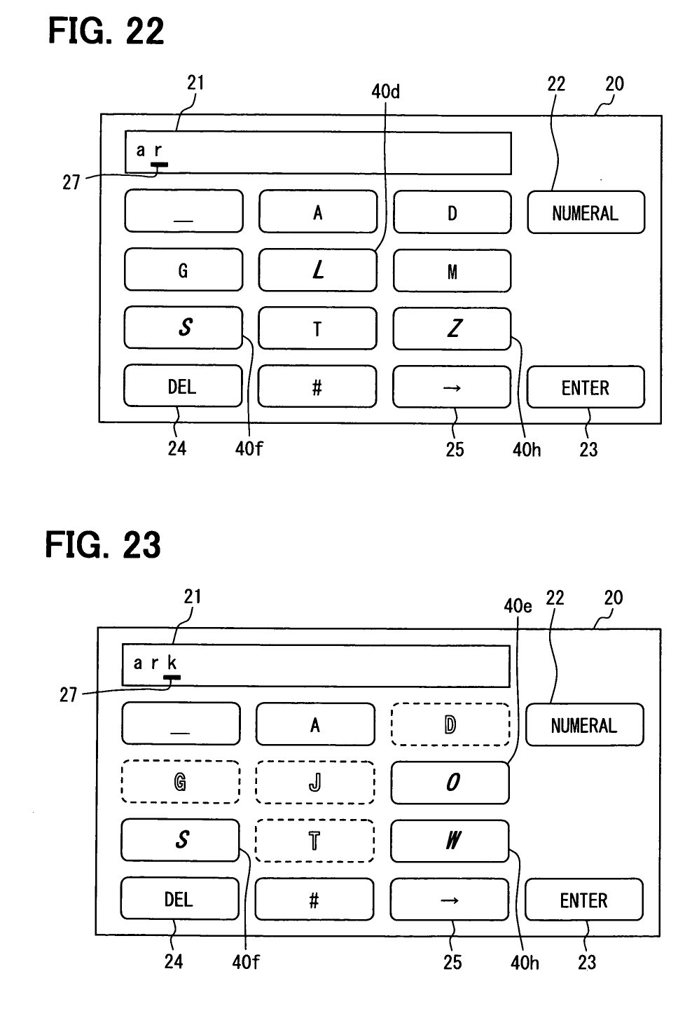

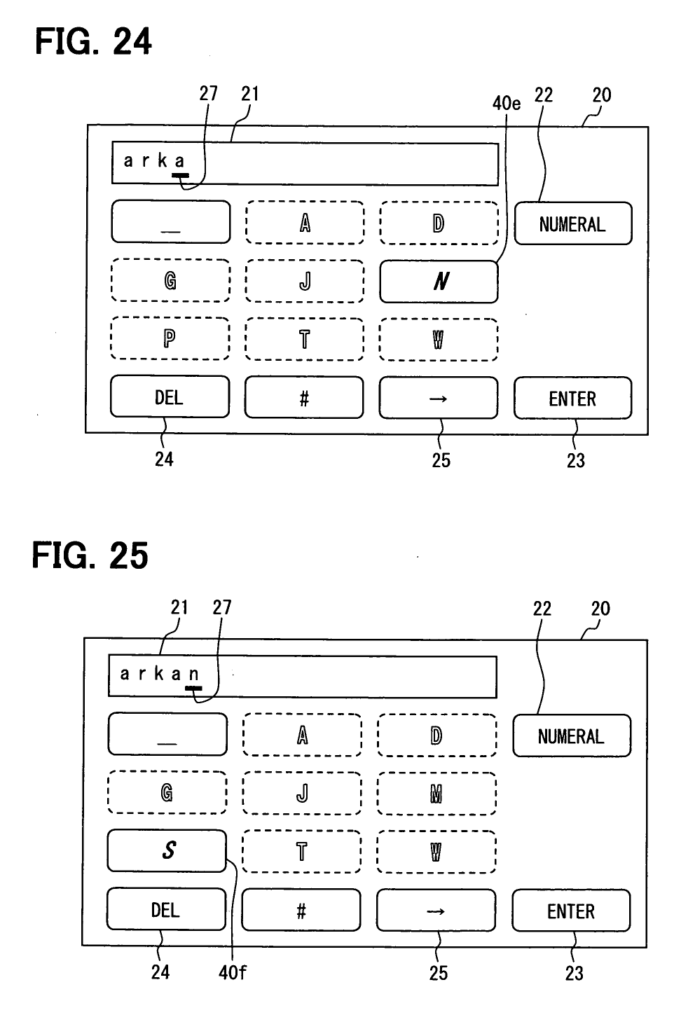

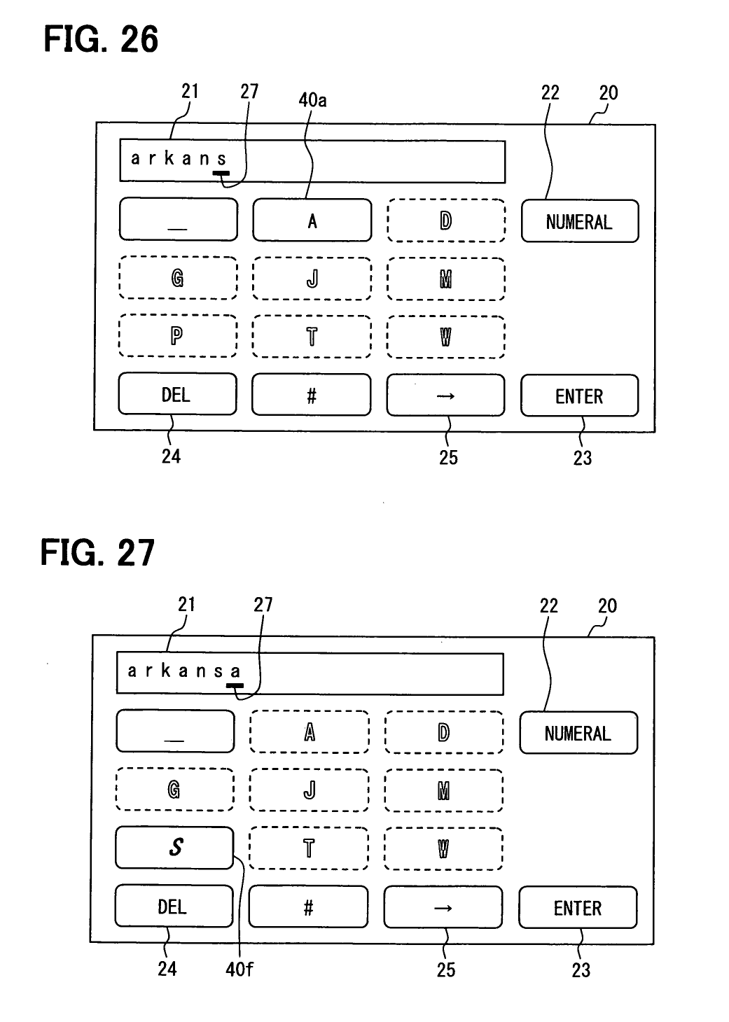

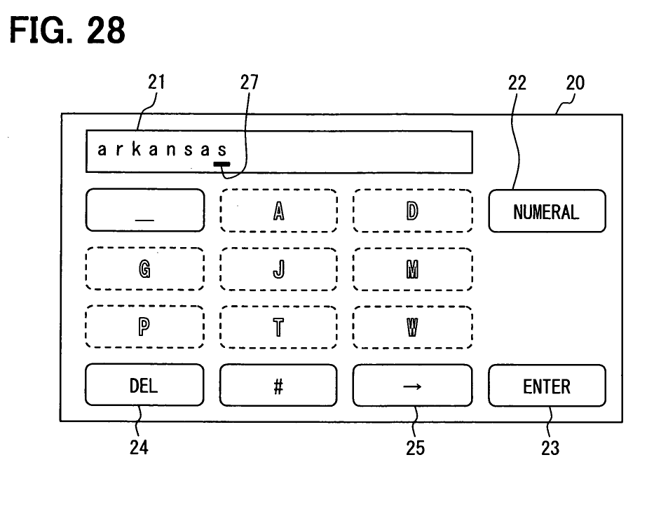

Next, further explanation is supplemented below with respect to the alphabetical character input mode as a third example of the present embodiment while further referring to FIGS. 18 to 28. For instance, similarly to that in the Japanese Hiragana character input mode, in the alphabetical character input mode, the tree structure index data with respect to a recorded target data item is used. The tree structure index data signifies a character row order within the target data item (refer to FIG. 19). For instance, the state of “Arkansas” in the United States of America is indicated in the tree structure index data according to the present example to teach a character row order as a series of “a-r-k-a-n-s-a-s” in eight alphabetical characters from a higher layer (leading position) to a lower layer (tailing position).

In other words, the tree structure index data includes a certain word as a recorded data item; the certain word is represented by a series of n characters. Herein, the tree structure index data teaches which character is allowed to follow i-th (i=0 to n-1) character. In fact, any character is naturally allowed to follow the zero-th character.

In an alphabetical character example, “Arkansas” is used again with reference to FIG. 19, which is only based on an example of the tree structure index data according to the present example. As the first or initial character, any character of “A” to “Z” is naturally allowed to follow the zero-th character. After “A” is inputted, any character or alphabetical character is still allowed to follow the first character of “A”. After “R” is inputted to follow “A”, characters except “W” and “X” are allowed to follow “AR” or the second character of “R”. After “K” is inputted to follow “AR”, only characters of “A”, “O”, “S”, and “W” are allowed to follow “ARK” or the third character “K”. After “A” is inputted to follow “ARK”, only a character of “N” is allowed to follow “ARKA” or the fourth character “A”. After “N” is inputted to follow “ARKA”, only a character of “S” is allowed to follow “ARKAN” or the fifth character “N”. After “S” is inputted to follow “ARKAN”, only a character of “A” is allowed to follow “ARKANS” or the sixth character “S”. After “A” is inputted to follow “ARKANS”, only a character of “S” is allowed to follow “ARKANSA” or the seventh character “A”. After “S” is inputted to follow “ARKANSA”, no character is allowed to follow “ARKANSAS” or the eighth character “S”.

Tracing the tree structure from an initial character (the leading character in the character string) by a character-to-character procedure in such tree structure index data enables easy designation of a character, which follows a certain character constituting a corresponding recorded data item.

FIG. 18 is an example of a character input reception display window 20 in the alphabetical character input mode. Herein, in FIG. 18, the same components as those in the character input reception window 20 in FIG. 9 are assigned with the identical reference numerals. Note that the input mode switch key 22 is represented by “NUMERAL”, which signifies that the numeral character input mode will take place when the input mode switch key 22 is appointed next.

The character input reception window 20 in the alphabetical character input mode replaces the Japanese Hiragana character input keys 30 in the Hiragana character input mode in FIG. 9 with multiple alphabetical character input keys 40, which can be individually appointed by the user.

Here, the alphabetical character input keys 40 are assigned individually with character groups different from each other. Herein, similar to the Japanese Hiragana character input keys 30, character groups including several alphabetical characters in the alphabetical order are individually assigned to the alphabetical character input keys 30. Further, several signs, e.g., “#”, “?”, “&”, are assigned to a sign input key 40i, which is displayed along with the alphabetical character input keys 40a to 40h in the alphabetical character input mode in the present example.

As shown in FIG. 18, the present example uses a typical keypad system such as a DTMF (Dual-Tone Multi-Frequency) keypad system. Eight character input keys 40a to 40h are provided in the character input reception window 20. As known, for instance, the “A” row input key 40a is assigned with a character group including “A”, “B”, and “C” with “A” being initial. For instance, the “P” row input key 40f is assigned with a character group including “P”, “Q”, “R”, and “S” with “P” being initial.

Further, if the character group of the “P” row key 40f is taken for an example, a corresponding initial-defined cyclic character row order, which is a cyclic character row order with an initial character being defined, is “P”→“Q”→“R”→“S”→“P”→“Q”→“R”→ . . . .

In addition, in the example of FIG. 18, the initial character within the character group of each alphabetical character input key 40 is used as a display image or display character for representing the character group of the corresponding input key in the default display form as shown in FIG. 18. However, such a configuration for using the initial character as the display character is only illustrated as an example of the display form according to the present example.

In the alphabetical character input mode, the subprogram 600 of FIG. 8 is executed by the display update process at S550 in FIG. 7. In addition, when one of the alphabetical character keys 40a to 40h is appointed in the alphabetical character input mode, the control circuit 17 executes the subprogram 200 of FIG. 4 like the case where the Japanese Hiragana character input key 30 is appointed. Therefore, the change in the display character for the alphabetical character input keys 40a to 40h is the same as those in the Japanese Hiragana character input keys 30.

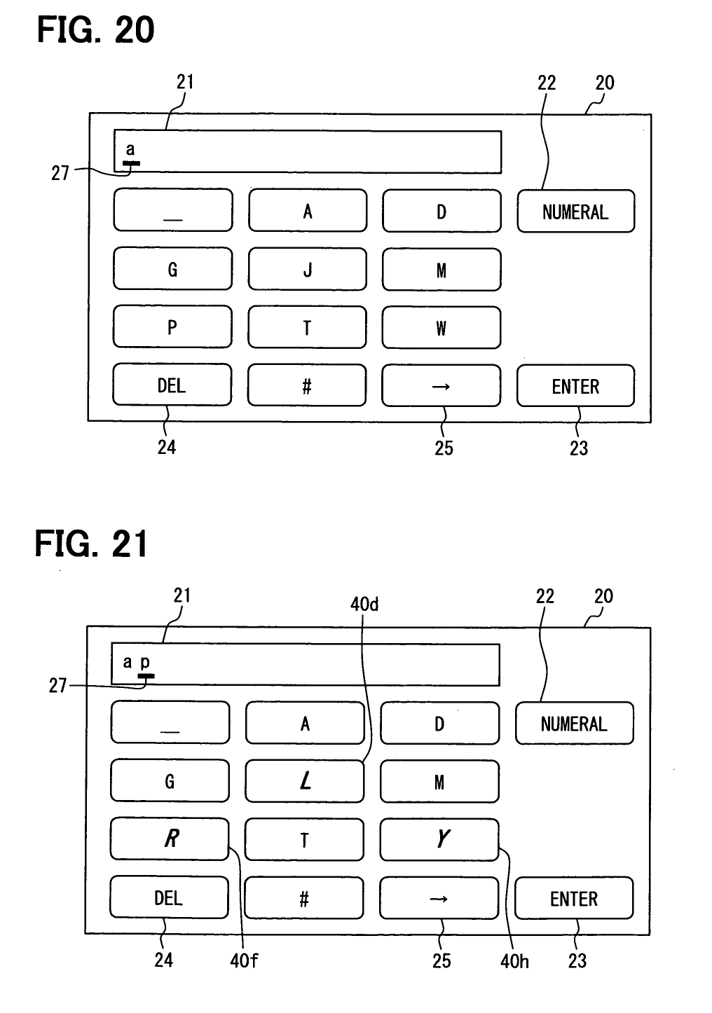

FIGS. 20 to 28 are exemplified as the changes according to the tree structure index data in FIG. 19 of the present example when the input character string of “a-r-k-a-n-s-a-s” is inputted serially. Herein, when display characters not being initial in each character group is displayed as the corresponding display character, those are illustrated in enlarged and italic forms just for easy recognition. Furthermore, the display character corresponding to the input key including all the characters being not effectively following the input character or input character string is illustrated in an outlined form also just for easy recognition.

(Effects)

The in-vehicle navigation apparatus 1 according to the present embodiment displays multiple character input keys 30, 40 in the first display portion in the image display device 12 and uses, as a display image for representing each character input key 30, 40, an image containing one of the characters assigned to the each character input key 30, 40.

Suppose the case that a user appoints, using the operation section 13, a first character input key 30, 40 among the multiple character input keys 30, 40. Such a first character input key is exemplified by each of the following keys. The “ [symbol] (a)” row input key 30a is appointed to thereby change the character input reception window 20 as shown in FIG. 10, FIG. 12, and FIG. 13; the “ [symbol] (ta)” row key 30d is appointed to thereby change the character input reception window 20 as shown in FIG. 14; and the “ [symbol] (ka)” row key 30b is appointed to thereby change the character input reception window 20 as shown in FIG. 15. In such cases, the display character for the first character input key is displayed as an input character in the second display portion of the input character string field 21 of the image display device 12, without waiting for any additional operation to the operation section 13 (refer to S205 to S235 in FIG. 4).

Further, when the user appoints the first character input key using the operation section 13, a display character for a second character input key included in the multiple character input keys 30, 40 is switched based on the contents of the character displayed as an input character by the user's appointment. Such a second character input key is exemplified by each of the following keys: the “ [symbol] (a)” row input key 30a in the example illustrated in FIG. 10; the “ [symbol] (a)” row input key 30a and “ [symbol] (ta)” row key 30d in the example in FIG. 13; the “ [symbol] (a)” row input key 30a, “ [symbol] (ka)” row key 30b, and “ [symbol] (ta)” row key 30d in the example in FIG. 14; and “ [symbol] (ka)” row key 30b and “ [symbol] (ta)” row key 30d in the example in FIG. 15.

Here, a predetermined character or predetermined character image, to which the display character for the second character input key is switched, is different from the character displayed as the display character just before the first character input key is appointed.

Further, the predetermined character designated as a next display character for the second character input key is selected based on (i) the character mode or kind displayed as an input character after the appointment of the input key and (ii) the used tree structure index data.

Thus, a single character input key 30, 40 is assigned with multiple characters and one of the multiple characters is displayed in the first display portion of the image display device 12 as a display character with respect to the single character input key 30, 40. The number of the character input keys 30, 40 in a single display window can be thereby reduced in comparison with the number of all the characters assigned individually to the multiple character input keys. The visibility and operability can be thus improved for users.

Then, when the user appoints one of those character input keys 30, 40, the character in the display character or display image for the appointed character input key is regarded as an input character. Furthermore, when the user appoints one of those character input keys 30, 40, based on the contents of the input character determined by the appointment, a new or next display character for the second character input key is determined.

Accordingly, two of (i) a character designated as an input character when a certain character input key is appointed and (ii) a display character for the certain character accord with each other. The user can thus clearly recognize, via vision, what kind of character is allowed to be subsequently inputted.

Further, when the user appoints a first character input key, the display character for the first character input key is displayed as a character positioned at the tail end of the input character string. The character positioned at the tail end of the input character string may include (i) a character, which is added to the tail end of the input character string and (ii) a character, which is substituted for the previous character positioned at the tail end.

In the above navigation apparatus 1, when the user appoints the first character input key, the display character for the second character input key is switched to a character, which is among the characters assigned to the second character input key and allowed to follow the input character string according to the tree structure index data.

Thus, the use of the tree structure index data containing multiple words allows designation of a character which the user possibly inputs. The designated character can be used as a display character for representing the second character input key. Thus, the user can easily perform a character input.

Further, in the navigation apparatus 1, in case that the user appoints the first character input key, if the user appointed the first character input key also at the previous appointment time, a display character, which is included in the display image of the first character input key, is displayed, as a substitute character to be substituted for the character arranged at the tail end of the input character string, in the second display portion (i.e., the input character string field 21) of the image display device 12. In such a case, when the first character input key is appointed successively, only the character at the tail end of the input character string changes one by one while the number of the characters of the input character string does not change.

Further, in such a case, an effective character following the preceding character string (i.e., the input determined character string) is extracted among all the characters included in the character group assigned to the first character input key. For instance, with reference to FIG. 13, “ [symbol] (a)”, “ [symbol] (e)”, and “ [symbol] (o)”, which are effective characters following “ [symbol] (a)” as the preceding input character string, are extracted. Furthermore, among the extracted characters, a character (“ [symbol] (e)” in FIG. 13), which is at the leading order next to the input character (“ [symbol] (i)” in FIG. 13) according to above-mentioned cyclic character row order is designated; thereby, the display character for the first character input key is switched to the designated character.

Thus, when the user appoints the first character input key successively, both (i) the display character for the first character input key and (ii) the character at the tail end of the input character string switch under the cyclic character row order between characters, which can effectively follow the preceding input character string according to the dictionary data.

Therefore, in the procedure which selects the character at the tail end of the input character string in the cyclic order by successively appointing the same input key 30, 40, the display character in the corresponding character input key also changes in the cyclic order synchronously. Therefore, even the user who does not know how to change in the cyclic character row order can recognize via vision clearly what kind of character is allowed to be inputted from now.

In addition, as another aspect, in the navigation apparatus 1, multiple character input keys 30, 40, each of which is assigned with several characters, are displayed in the first display portion of the image display device 12. When the user appoints one of the multiple character input keys 30, 40 using the operation section 13 (refer to S120), one character is selected as corresponding to the number of times in the successive appointments of a certain character input key from among several characters assigned to the certain character input key. The selected character is displayed in the second display portion (i.e., input character string field 21) of the image display device 12 as an input character (refer to S205 to S235).

Further, with respect to each of the above multiple character input keys 30, 40, an image containing one of the several characters assigned to each character input key is adopted as an image which represents the corresponding character input key (refer to S110, S240, S270, and S280).

Suppose the case that a user appoints, using the operation section 13, a first character input key 30, 40 among the multiple character input keys 30, 40. Such a first character input key is is exemplified by each of the following keys. The “ [symbol] (a)” row input key 30a is appointed to thereby change the character input reception window 20 as shown in FIG. 10, FIG. 12, and FIG. 13; the “ [symbol] (ta)” row key 30d is appointed to thereby change the character input reception window 20 as shown in FIG. 14; and the “ [symbol] (ka)” row key 30b is appointed to thereby change the character input reception window 20 as shown in FIG. 15. In such cases, if the user then appoints a second character input key once among the multiple character input keys 30, 40, a next input candidate character, which is probably designated as the input character, is designated (refer to S240, S280).

An image for representing the second character input key is switched to an image containing the designated next input candidate character (refer to S270, S280).

Such a second character input key is exemplified by each of the following keys: the “ [symbol] (a)” row input key 30a in the example illustrated in FIG. 10; the “ [symbol] (a)” row input key 30a and “ [symbol] (ta)” row key 30d in the example in FIG. 13; the “ [symbol] (a)” row input key 30a, “ [symbol] (ka)” row key 30b, and “ [symbol] (ta)” row key 30d in the example in FIG. 14; and “ [symbol] (ka)” row key 30b and “ [symbol] (ta)” row key 30d in the example in FIG. 15.

Thus, two or more characters are assigned to each displayed character input key; further, one of the assigned characters included in a display image for the corresponding character input key is displayed in the image display device 12.

Thus, the number of the character input keys in a single display window can be thereby reduced in comparison with the number of all the characters assigned to the multiple character input keys. The visibility and operability can be improved for users.

Further, when the user appoints one of the character input keys, a character, which is included in the corresponding character group and corresponds to the number of times of the successive appointments, is designated as an input character. Therefore, by successively appointing a certain character input key the number of appropriate several times, the user can input a desired character assigned to the relevant character input key.

In addition, when the user appoints a first character input key, a display character for a second character input key is turned into a character corresponding to the number of times in the successive appointments (refer to S210, S220, and S240). In addition, in each of the multiple character input keys, the correspondence relation between (i) the number of times of the successive appointments and (ii) the designated character is designed to change based on (i) the contents of the input character just prior to the appointment and (ii) an effective character according to the tree structure index data.

The display character of the character input key thus changes dynamically. The input character designated when a certain character input key 30, 40 is appointed and the display character for the appointed certain character input key accord with each other. The user can thus clearly recognize, via vision, what kind of character is allowed to be subsequently inputted.

### Other Embodiments

While there have been described specific preferred embodiments of the present invention, it is to be distinctly understood that the present invention is not limited thereto and includes various modes capable of embodying functions of specifics of the present invention.

For example, the second display portion which displays the input character string 28, and the first display portion which displays the character input keys 30, 40 may be provided in different separate image display devices.

In addition, the default display form (refer to FIG. 9) displayed at S110 in FIG. 3 may be modified alternatively. By executing S620 to S630, or S620 to S640 in FIG. 8, a character, which is not an effective character following the null character according to tree structure index data, may be reflected to thereby determine the display character of each character input key 30, 40. In addition, with respect to such a case, it can be determined whether a corresponding display character should be toned down or not.

In addition, the tree structure index data is used as the dictionary data about reading or Hiragana character row order of words in the above embodiment. The dictionary data may not have the tree structure. If the dictionary data contains data about the reading or the character row order of the recorded data items (e.g., facility names, land lot numbers, etc.), the present embodiment can use it. If the character input reception apparatus has a sufficient throughput capability, the dictionary data which does not have the tree structure can also be practically used.

In addition, the present invention is also applicable to a character input reception apparatus which does not have dictionary data. In the apparatus, suppose a case that when a user performs an appointment of a first character input key, it is determined that the immediately previous appointment is also performed to the first character input key. In such a case, a character, which is included in a display image for the first character input key, is displayed as a substitute input character to replace the character arranged at the tail end of the input character string in the image display device 12.

Further, in parallel, the display character for the first character input key is switched into a character, which is included in a character group assigned to the first character input key and next to the above input character in the cyclic character row order.

Thus, when the user appoints the first character input key successively, both (i) the display character for the first character input key and (ii) the character at the tail end of the input character string switch under the cyclic character row order between characters assigned to the first character input key.

Therefore, in the procedure which selects the character at the tail end of the input character string in the cyclic order, the display character for the corresponding character input key also changes in the cyclic order synchronously. Therefore, even a user, who does not know the procedure of the cyclic order, can recognize via vision clearly what kind of character is allowed to be inputted from now.

According to the above embodiment, the control circuit 17 performs the programs to implement the functions. The functions may be achieved by a hardware device having the equivalent functions. Such hardware device examples include an FPGA capable of programming a configuration of the circuit.

In addition, although the in-vehicle navigation apparatus 1 is used as a character input reception apparatus in the above embodiment, the character input reception apparatus according to the present invention can be directed or applicable, without being limited to the navigation apparatus 1, to another apparatus, which receives character inputs using key displays, such as a cellular phone, PDA, touch sensitive character input device installed in shops including convenience stores.

Each or any combination of processes, steps, or means explained in the above can be achieved as a software portion or unit (e.g., subroutine) and/or a hardware portion or unit (e.g., circuit or integrated circuit), including or not including a function of a related device; furthermore, the hardware portion or unit can be constructed inside of a microcomputer.

Furthermore, the software portion or unit or any combinations of multiple software portions or units can be included in a software program, which can be contained in a computer-readable storage media or can be downloaded and installed in a computer via a communications network.

Aspects of the disclosure described herein are set out in the following clauses.

As an aspect of the disclosure, a character input reception apparatus is provided as follows. A key display control portion and an input character display control portion are included. The key display control portion is configured to (i) display a plurality of character input keys in a first display portion, each character input key being assigned with a character group including a plurality of characters, and (ii) designate one of the plurality of characters assigned to each character input key so as to display the designated one as a display character for the each character input key. The input character display control portion is configured to, when a user appoints a first character input key among the plurality of character input keys by using an operation section, display, as an input character, a display character for the first character input key in a second display portion. Herein, the key display control portion is further configured to, when the user appoints the first character input key using the operation section, switch a display character for a second character input key, which is one of the plurality of character input keys, from a first character to a second character different from the first character based on a content of a character displayed as an input character in response to appointing the first character input key by the input character display control portion, each of the first character and the second character being included in a character group with which the second character input key is assigned.

Herein, a display character for a certain character input key can be a character contained in a display image of the certain character input key.

Further, the first character input key and the second character input key may be identical to each other or different from each other. For example, the second character input key may be selected from among the plurality of character input keys based on the content of the character, which is displayed as an input character when the first character input key is appointed.

In addition, the first display portion for displaying the character input keys and the display portion for displaying the input character may be included in the same image display device or separately provided in the different image display devices.

Under the configuration according to the above aspect, a single character input key is assigned with multiple characters and one of the multiple characters is displayed as a display character for representing the single character input key in the first display portion. The number of the character input keys in a single display window or the first display portion can be thereby reduced in comparison with the number of all the characters assigned to the multiple character input keys. The visibility and operability can be improved for users.

Then, when the user appoints one of those character input keys, the display character for the appointed key turns into an input character. Furthermore, when the user appoints one of those character input keys, based on the contents of the input character determined by the appointment, a new display character for the second character input key is determined.

Thus, in other words, a character turning into an input character in response to an appointment of a certain character input key can accord with a display character for presenting the certain character input key just before the appointment. The user can thus clearly recognize, via vision, what kind of character is allowed to be subsequently inputted.

As an optional aspect of the character input reception apparatus, the input character display control portion may be further configured to, when the user appoints the first character input key, display the display character for the first character input key as a character arranged at a tail end of an input character string (28) in the second display portion. Further, the input character display control portion may be further configured to, when the user appoints the first character input key, switch the display character for the second character input key from the first character to the second character, the second character being allowed to follow the input character string according to dictionary data.

Herein, “ . . . a character arranged at a tail end of an input character string . . . ” may signify either a character, which is added to the character at the tail end of the input character string, or a character, which is a substitute of the character at the tail end of the input character string.

Further, the use of the dictionary data containing multiple words allows designation of a character which the user possibly inputs. The designated character can be used as a display character for representing the second character input key. Thus, the user can easily perform a character input.

As an optional aspect of the character input reception apparatus, a cyclic character row order may be predetermined among the characters in the character group assigned to the first character input key. Further, the input character display control portion may be further configured to, when the user appoints the first character input key, display a display character, which is displayed for representing the first character input key, as a substitute character to replace a character arranged at the tail end of an input character string in the second display portion based on the first character input key having been appointed at a previous time. Furthermore, the input character display control portion may be further configured to, when the user appoints the first character input key, (i) extract, among the character group assigned to the first character input key, all characters which are allowed to be a character following, of the input character string, a preceding input character string just before the input character, and (ii) switch the display character for the first character input key into a character which is a leading character next to the input character in the predetermined cyclic character row among the extracted all characters.

Under such a configuration, when the first character input key is appointed successively, only the character at the tail end of the input character string changes one by one while the number of the characters of the input string does not change.

Further, when the user appoints the first character input key, the following takes place. That is, the display character in the first character input key and the character at the tail end of the input character string switch under the cyclic character row order between characters, which can effectively follow the preceding character string according to the dictionary data.

Therefore, in the procedure which selects the character at the tail end of the input string in the cyclic character row order, the display character for the corresponding character input key also changes in the cyclic character row order synchronously. Thus, even a user who does not know how to change in the cyclic character row order can recognize via vision clearly what kind of character is allowed to be inputted from now.

As an optional aspect, the character input reception apparatus may further includes a sound output control portion configured to, when the user appoints the first character input key, output via a speaker (i) a first sound or (ii) a second sound different from the first sound, based on a switching display character. Herein, the switching display character for the first character input key is a character into which the display character for the first character input key is switched in response to appointing the first character input key. The first sound may be outputted when the switching display character follows the input character according to the predetermined cyclic character row order. In contrast, the second sound is outputted when the switching character does not follow the input character according to the predetermined cyclic character row order.

Under such a configuration, only when the second sound is outputted, it may be necessary to confirm the display character. In contrast, when the first sound is outputted, it may be unnecessary to confirm the display character.

As an optional aspect of the character input reception apparatus, a cyclic character row order may be predetermined among the characters in the character group assigned to the first character input key. Herein, the input character display control portion may be further configured to, when the user appoints the first character input key, display a display character, which is displayed for the first character input key, as a substitute character to replace a character arranged at the tail end of an input character string in the second display portion based on the first character input key having been appointed at a previous time. Further, the input character display control portion may be further configured to, when the user appoints the first character input key, switch a display image representing the first character input key into a character, which follows the input character in the cyclic character row order and is included in the character group assigned to the first character input key.

Under such configuration, when the user appoints the first character input key successively, the display character for the first character input key and the character at the tail end of the input character string switch among the characters assigned to the first character input key in the cyclic character row order.

Therefore, in the procedure which selects the character at the tail end of the input string in the cyclic character row order, the display character in the corresponding character input key also changes in the cyclic character row order synchronously. Therefore, even a user who does not know how to change in the cyclic character row order can recognize via vision clearly what kind of character can be inputted from now.

As another aspect of the disclosure, a character input reception apparatus is provided as follows. A key display control portion and an input character display control portion are included. The key display control portion is configured to display in a first display portion a plurality of character input keys, each character input key being assigned with a character group including a plurality of characters. The input character display control portion is configured to, when the user appoints one of the character input keys using an operation section, (i) select, among the plurality of characters assigned to the appointed one of the character input keys, a character corresponding to a number of times in successively appointing the one of the character input keys and (ii) display the selected character as an input character in a second display portion. Herein, the key display control portion is further configured to designate, as a display character for each of the plurality of character input keys, one of the plurality of characters included in the character group assigned to the each of the plurality of character input keys. In addition, the key display control portion is further configured to, in case that the user appoints a first character input key among the plurality of character input keys using the operation section, (i) designate a next input candidate character assigned to a second character input key included in the plurality of character input keys, the next input candidate character being to be designated as a next input character by the input character display control portion if the user subsequently appoints the second character input key once, and (ii) switch a display character for the second character input key into the designated next input candidate character.

Herein, when a certain key is appointed once, the number of times of successive appointments of the key is assumed to be one time.

Under the above configuration, in particular, when the user appoints one of the character input keys, a character corresponding to the number of times of successive appointments turns into an input character within the relevant character group. Therefore, by performing successive appointments of a certain character input key appropriate times, the user can input a desired character assigned to the certain character input key.

Further, when the first character input key is appointed, a display character for representing the second character input key turns into a next input candidate character, which is estimated as a next input character following the input character displayed in response to the number of times of successive appointments of the first character input key. In addition, the second character input key can be identical to or different from the first character input key. In addition, in each of the multiple character input keys, the correspondence relation between the character and the number of times of successive appointments may change based on contents of the input character just before.

In particular, under the above configuration, the display character for the character input key changes dynamically. An input character designated when a certain character input key is appointed and a display character for the appointed certain character input key accord with each other. The user can thus clearly recognize, via vision, what kind of character is allowed to be inputted.

It will be obvious to those skilled in the art that various changes may be made in the above-described embodiments of the present invention. However, the scope of the present invention should be determined by the following claims.

What is claimed is:

1. A character input reception apparatus comprising:
a key display control portion configured to
(i) display a plurality of character input keys in a first display portion, each character input key being assigned with a character group including a plurality of characters, and
(ii) designate one of the plurality of characters assigned to each character input key so as to display the designated one as a display character for the each character input key; and
an input character display control portion configured to, when a user appoints a first character input key among the plurality of character input keys by using an operation section, display, as an input character, a display character for the first character input key in a second display portion,
the key display control portion being further configured to, when the user appoints the first character input key using the operation section, switch a display character for a second character input key, which is one of the plurality of character input keys, from a first character to a second character different from the first character based on a content of a character displayed as an input character in response to appointing the first character input key by the input character display control portion, each of the first character and the second character being included in a character group with which the second character input key is assigned.

2. The character input reception apparatus according to claim 1,
wherein the input character display control portion is further configured to, when the user appoints the first character input key, display the display character for the first character input key as a character arranged at a tail end of an input character string in the second display portion; and
wherein the input character display control portion is further configured to, when the user appoints the first character input key, switch the display character for the second character input key from the first character to the second character, the second character being allowed to follow the input character string according to dictionary data.

3. The character input reception apparatus according to claim 1,
wherein a cyclic character row order is predetermined among the characters in the character group assigned to the first character input key;
wherein the input character display control portion is further configured to, when the user appoints the first character input key, display a display character, which is displayed for the first character input key, as a substitute character to replace a character arranged at the tail end of an input character string in the second display portion based on the first character input key having been appointed at a previous time; and
wherein the input character display control portion is further configured to, when the user appoints the first character input key,
(i) extract, among the character group assigned to the first character input key, all characters which are allowed to be a character following, of the input character string, a preceding input character string just before the input character, and
(ii) switch the display character for the first character input key into a character which is a leading character next to the input character in the predetermined cyclic character row among the extracted all characters.

4. The character input reception apparatus according to claim 3, further comprising:
a sound output control portion configured to, when the user appoints the first character input key, output via a speaker (i) a first sound or (ii) a second sound different from the first sound based on a switching display character for the first character input key, the switching display character being a character into which the display character for the first character input key is switched in response to appointing the first character input key,
the first sound being outputted when the switching display character follows the input character according to the predetermined cyclic character row order,
the second sound being outputted when the switching character does not follow the input character according to the predetermined cyclic character row order.

5. The character input reception apparatus according to claim 1,
wherein a cyclic character row order is predetermined among the characters in the character group assigned to the first character input key;
wherein the input character display control portion is further configured to, when the user appoints the first character input key, display a display character, which is displayed for the first character input key, as a substitute character to replace a character arranged at the tail end of an input character string in the second display portion based on the first character input key having been appointed at a previous time; and
wherein the input character display control portion is further configured to, when the user appoints the first character input key, switch a display image representing the first character input key into a character, which follows the input character in the cyclic character row order and is included in the character group assigned to the first character input key.

6. A character input reception apparatus, comprising:
a key display control portion configured to display in a first display portion a plurality of character input keys, each character input key being assigned with a character group including a plurality of characters; and
an input character display control portion configured to, when the user appoints one of the character input keys using an operation section,
(i) select, among the plurality of characters assigned to the appointed one of the character input keys, a character corresponding to a number of times in successively appointing the one of the character input keys and
(ii) display the selected character as an input character in a second display portion,
the key display control portion being further configured to designate, as a display character for each of the plurality of character input keys, one of the plurality of characters included in the character group assigned to the each of the plurality of character input keys,
the key display control portion being further configured to, in case that the user appoints a first character input key among the plurality of character input keys using the operation section,
(i) designate a next input candidate character assigned to a second character input key included in the plurality of character input keys, the next input candidate character being to be designated as a next input character by the input character display control portion if the user subsequently appoints the second character input key once, and
(ii) switch a display character for the second character input key into the designated next input candidate character.

7. A method for receiving character inputs using an image display device, the method comprising:
displaying a plurality of character input keys in a first display portion of the image display device, the plurality of character input keys at least including a first character input key and a second character input key, each of the plurality of character input keys being assigned with an individual character group including a plurality of individual characters;
designating one of the plurality of individual characters assigned to each character input key;
displaying a display character for representing the each character input key by using the designated one of the plurality of individual characters;
displaying, when the first character input key is appointed, an input character in a second display portion of the image display device by using a display character, which is displayed for representing the first character input key just before the first character input key is appointed; and
switching a display character for representing the second character input key from a first character to a second character based on a content of the input character displayed in the second display portion in response to appointing the first character input key, each of the first character and the second character being included in a character group with which the second character input key is assigned.

8. A method for receiving character inputs using an image display device, the method comprising:
displaying in a first display portion a plurality of character input keys, the plurality of character input keys at least including a first character input key and a second character input key, each of the plurality of character input keys being assigned with an individual character group including a plurality of individual characters;
designating one of a plurality of characters assigned to the second character input key;
displaying a display character for representing the second character input key by using the designated one of the plurality of characters assigned to the second character input key;
selecting, when the first character input key is appointed, a character corresponding to a number of times in successively appointing the first character input key from among a plurality of characters assigned to the first character input key;
displaying the selected character as an input character in a second display portion of the image display device;
designating, among a plurality of characters assigned to the second character input key, a next input candidate character, which is estimated to be designated as a next input character following the input character in the second display portion if the second character input key is subsequently appointed once after the first character input key is appointed; and
switching a display character for representing the second character input key into the designated next input candidate character in response to appointing the first character input key.

9. A program storage medium containing instructions readable and executable by a computer, the instruction for causing the computer to function as the input character display control portion and the key display control portion included in the character input reception apparatus according to claim 1.

10. A program storage medium containing instructions readable and executable by a computer, the instruction for causing the computer to function as the input character display control portion and the key display control portion included in the character input reception apparatus according to claim 6.
